(19) United States
(12) Patent Application Publication
(10) Pub. No.: US 2004/0058492 A1
(43) Pub. Date: Mar. 25, 2004

(54) Vapor growth method for metal oxide dielectric film and pzt film

(76) Inventor: Toru Tatsumi, Tokyo (JP)

Correspondence Address: SUGHRUE MION, PLLC, 2100 PENNSYLVANIA AVENUE, N.W., SUITE 800, WASHINGTON, DC, 20037, US

(21) Appl. No.: 10/471,104

(22) PCT Filed: Mar. 11, 2002
(86) PCT No.: PCT/JP02/02229

(30) Foreign Application Priority Data
Mar. 9, 2001 (JP) 2001-067133

(51) Int. Cl. H01L 21/31; H01L 21/8242; H01L 21/469

(52) U.S. Cl. 438/240; 438/785

(57) ABSTRACT

For forming a metal-oxide dielectric film having a perovskite type of crystal structure represented by ABO₃ on a base conductor material using organometallic source gases, initial perovskite crystal nuclei or an initial amorphous layer having an amorphous structure are formed on the base conductor material under the first deposition conditions; and a film having a perovskite crystal structure is further grown on the initial crystal nuclei or the initial amorphous layer under the second deposition conditions. In the process, the first deposition conditions meet at least one of the requirements: (a) a lower substrate temperature than that in the second deposition conditions; and (b) a higher source gas pressure than that in the second deposition conditions. This process can be used to deposit a film such as PZT exhibiting a reduced leak current.

### TECHNICAL FIELD

This invention relates to a process for manufacturing a semiconductor device comprising a capacitive element. In particular, it relates to a process for depositing a high-dielectric or ferroelectric film for a capacitor or gate in a semiconductor integrated circuit, using organometallic source gases.

### BACKGROUND ART

Recently, ferroelectric memories utilizing a ferroelectric capacitor as well as dynamic random access memories (DRAMs) have been intensely studied and developed. These ferroelectric memories and DRAMs comprise a selection transistor. They uses, as a memory cell, a capacitor connected to one of the diffusion layers in the selection transistor to store information. A ferroelectric capacitor comprises a ferroelectric film made of, for example, Pb(Zr,Ti)O₃ (hereinafter, referred to as “PZT”) as a capacitor insulating film and can store nonvolatile information by polarizing the ferroelectric material. On the other hand, a high-dielectric capacitor uses a high-dielectric film made of, for example, (Ba,Sr)TiO₃ (hereinafter, referred to as “BST”) as a capacitor insulating film so that a capacitance of the capacitor can be improved and can thus miniaturize a device. When using such a ceramic material in a semiconductor device, it is very important to electrically separate the ceramic material deposited on a conducting layer to be a lower electrode, as a fine capacitor.

Sol-gel, sputtering and CDV techniques have been previously described as a process for depositing a film.

For achieving ferroelectricity, a material must be crystallized in an aligned orientation. In sol-gel or sputtering technique, a deposited film must be annealed at an elevated temperature under oxygen atmosphere for crystallization. A crystallization temperature for adequate ferroelectric properties is 600° C. for a metal-oxide dielectric film made of PZT and 650° C. for that made of BST. A crystalline metal-oxide dielectric film cannot be, therefore, formed on a semiconductor substrate after forming aluminum interconnections. Furthermore, sol-gel technique is not applicable to a wafer with a large diameter and provides an inadequate step coverage. In sputtering, a film composition substantially depends on a target composition. Thus, for changing a film composition, a target must be replaced, which is disadvantageous in the light of a process efficiency.

CVD technique gives good uniformity and a good coverage to a surface step in a large diameter wafer, and is, therefore, believed to be a promising process for a ULSI.

Japanese Laid-open Patent Publication 2000-58525 has described a chemical vapor deposition (CVD) process for forming a perovskite type of metal-oxide dielectric film on a lower electrode using organometallic source gases and an oxidizing gas wherein initial crystal nuclei or an initial crystal layer are/is formed under the first conditions and a film is deposited at a feeding rate of source gases under the second conditions instead of the first conditions without changing a deposition temperature. According to this process, a perovskite type crystal exhibiting good orientation can be deposited formed at a temperature of about 450° C. or lower on a metal such as Pt, Ru and Ir or an oxide conductor electrode such as RuO₂ and IrO₂. A metal-oxide dielectric film can be, therefore, formed on a semiconductor substrate after forming aluminum interconnections and its higher capacitance permits size reduction of a device.

On the other hand, a source voltage must be reduced for high speed operation and size reduction and a ceramic capacitor insulating film must be made thinner for applying a sufficient electric field to the capacitor insulating film. However, the thinner the film is, the more significant a leak current is. Even by the process disclosed in Japanese Laid-open Patent Publication 2000-58525, a considerable leak current may be generated under certain conditions. The problem is particularly significant when using Ru, Ir or an oxide such as RuO₂ and IrO₂ as a material for a lower electrode in a capacitor.

In a ferroelectric memory (FeRAM), data are read out by detecting the increased amount in a bit line voltage raised by the charge fixed by the spontaneous polarization in comparison with a bit line voltage of an adjacent capacitor written in an inverse direction by a sensor amplifier. If the difference in a bit line electrode is below 50 mV which is a detection limit for the sensor amplifier, the bit is defective. For improving an yield for a chip, it is necessary to increase a bit line voltage difference, i.e., to considerably improve a hysteresis property. However, when a number of memories are integrated, a bit line voltage difference vary between capacitive elements. A few of defective bits are, therefore, often formed in a distribution tail.

Furthermore, in a practical process for manufacturing a semiconductor device, mask alignment must be repeated in a lithography process. After deposition of a metal oxide dielectric film such as a PZT, a film, depending on its crystallization state, may become opaque, causing irregular reflection such that an alignment mark becomes obscure, leading to difficulty in subsequent alignment. The problem of deterioration in processability of a film is particularly significant when using Ru, Ir or an oxide such as RuO₂ and IrO₂ as a material for a lower electrode in a capacitor.

### DISCLOSURE OF THE INVENTION

In view of the problems in the prior art, an objective of this invention is to provide a vapor growth process for an oxide dielectric film, particularly a PZT film (Pb(Zr,Ti)O₃ film) with a reduced leak current. Another objective of this invention is to provide a vapor growth process for a PZT film wherein even after deposition of the PZT film, the film exhibits good flatness, thus irregular reflection is reduced and mask alignment can be smoothly conducted. An objective of one aspect of this invention is to provide a process for manufacturing an oxide dielectric film which can be applied to capacitive element formation with reduced variation in a bit line voltage difference between capacitive elements and with a minimum number of defective bits.

This invention provides a vapor growth process for forming a metal-oxide dielectric film having a perovskite type of crystal structure represented by ABO₃ on a base conductor material using organometallic source gases, comprising the first step of forming initial perovskite crystal nuclei or an initial amorphous layer having an amorphous structure on the base conductor material under the first deposition conditions and the second step of further growing a film having a perovskite crystal structure on the initial crystal nuclei or the initial amorphous layer formed in the first step under the second deposition conditions which are different from the first deposition conditions;

wherein the first conditions meet at least one of the following requirements:

(a) a lower substrate temperature than that in the second deposition conditions; and

(b) a higher source gas pressure than that in the second deposition conditions.

A preferable aspect of this invention provides the above process wherein all of the organometallic source gases to be materials for a metal-oxide dielectric are used under the first deposition conditions to form initial nuclei or an initial amorphous layer and a film having a perovskite crystal structure is grown using all of the organometallic source gases under the second deposition conditions while changing the feeding conditions.

Another preferable aspect of this invention provides the above process wherein a portion of the organometallic source gases to be materials for a metal-oxide dielectric are used under the first deposition conditions to form initial nuclei or an initial amorphous layer and a film having a perovskite crystal structure is grown using all of the organometallic source gases under the second deposition conditions.

A process according to this invention is applicable to a manufacturing process for a semiconductor device having a capacitive element. Three typical embodiments are:

a process for manufacturing a semiconductor device comprising steps of forming an MOS transistor on a semiconductor substrate; forming a first interlayer insulating film on the transistor; opening, in the first interlayer insulating film, a contact reaching a diffusion layer in the MOS transistor and filling the contact with a metal plug for electric conduction; forming a capacitor lower electrode layer over the whole surface of the first interlayer insulating film having the metal plug; depositing a metal-oxide dielectric film using the above chemical vapor deposition method over the capacitor lower electrode layer; forming a capacitor upper electrode layer over the metal-oxide dielectric film; patterning the lower electrode layer, the metal-oxide dielectric film and the capacitor upper electrode layer to provide a three-layer structure capacitor;

a process for manufacturing a semiconductor device comprising steps of forming an MOS transistor on a semiconductor substrate; forming a first interlayer insulating film on the transistor; opening, in the first interlayer insulating film, a contact reaching a diffusion layer in the MOS transistor and filling the contact with a metal plug for electric conduction; forming a capacitor lower electrode layer over the whole surface of the first interlayer insulating film having the metal plug; patterning the capacitor lower electrode layer to form a capacitor lower electrode in the metal plug; depositing a metal-oxide dielectric film using the above chemical vapor deposition method over the whole surface of the patterned capacitor lower electrode and the first interlayer insulating film; forming a capacitor upper electrode layer over the whole surface of the metal-oxide dielectric film; and patterning the capacitor upper electrode layer to provide a three-layer structure capacitor comprising the capacitor lower electrode, the metal-oxide dielectric film and the capacitor upper electrode; and

a process for manufacturing a semiconductor device comprising steps of forming an MOS transistor on a semiconductor substrate; forming a first interlayer insulating film on the transistor; opening, in the first interlayer insulating film, a contact reaching a diffusion layer in the MOS transistor and filling the contact with a metal plug for electric conduction; forming an aluminum interconnection electrically connected to the metal plug on the first interlayer insulating film; forming a second interlayer insulating film on the aluminum interconnection; opening, in the second interlayer insulating film, a contact reaching the aluminum interconnection and filling the contact with a metal plug for electric conduction; forming a capacitor lower electrode layer over the whole surface of the second interlayer insulating film including the metal plug; depositing a metal-oxide dielectric film over the whole surface of the capacitor lower electrode layer by the above chemical vapor deposition method; forming a capacitor upper electrode layer over the whole surface of the metal-oxide dielectric film; and patterning the capacitor lower electrode layer, the metal-oxide dielectric film and the capacitor upper electrode layer to provide a three-layer structure capacitor.

The aluminum interconnection may be of a multilayer structure.

### BRIEF DESCRIPTION OF THE DRAWINGS

FIG. 1 schematically shows PZT growth by low-temperature or high-pressure nucleation technique.

FIG. 2 schematically shows nucleus formation in the low-temperature nucleation.

FIG. 3 schematically shows nucleus formation in the high-pressure nucleation.

FIG. 4 is a schematic phase diagram showing a crystallization and an amorphous phases in depositing a PZT film.

FIG. 5 shows an atomic force microscopy image (photograph) of a surface of a Ru base metal film when lead titanate nucleation is conducted at 450° C.

FIG. 6 shows an atomic force microscopy image (photograph) of a surface of a Ru base metal film when lead titanate nucleation is conducted at 410° C.

FIG. 7 shows an atomic force microscopy image (photograph) of a surface of a Ru base metal film when lead titanate nucleation is conducted at 360° C.

FIG. 8 are atomic force microscopy images (photographs) sequentially showing a chemical vapor deposition process.

FIG. 9 shows a scanning electron microscopy image (photograph) of a surface when nucleation and PZT deposition are conducted at 450° C. and 450° C., respectively.

FIG. 10 shows a scanning electron microscopy image (photograph) of a surface when nucleation and PZT deposition are conducted at 380° C. and 450° C., respectively.

FIG. 11 shows a transmission electron microscopy image (photograph) of a surface when nucleation and PZT deposition are conducted at 450° C. and 450° C., respectively.

FIG. 12 shows a transmission electron microscopy image (photograph) of a surface when nucleation and PZT deposition are conducted at 380° C. and 450° C., respectively.

FIG. 13 shows a transmission electron microscopy image (photograph) of a surface when nucleation and PZT deposition are conducted at 350° C. and 450° C., respectively.

FIG. 14 shows a leak current property when nucleation and PZT deposition are conducted at 350° C. and 450° C., respectively.

FIG. 15 shows a leak current property when nucleation and PZT deposition are conducted at 450° C. and 450 ° C., respectively.

FIG. 16 shows a hysteresis property when PZT is deposited varying a nucleation temperature.

FIG. 17 shows a fatigue property when PZT is deposited varying a nucleation temperature.

FIG. 18 shows a hysteresis property when a PZT deposition temperature is varied while maintaining a nucleation temperature at 380° C.

FIG. 19 shows atomic force electromicroscopy images (photographs) of a film surface after forming a nucleus at a nucleation pressure of (a) 0.1 Torr and (b) 1 Torr and then depositing a PZT film at 0.1 Torr in the second step.

FIG. 20 shows a hysteresis property of a film formed when conducting high pressure nucleation at 1 Torr.

FIG. 21 shows relationship between a nucleation pressure and a grain size.

FIG. 22 shows leak current properties for films after forming a nucleus at a nucleation pressure of (a) 0.1 Torr and (b) 1 Torr and then depositing a PZT film at 0.1 Torr in the second step.

FIG. 23 shows relationship between a grain size and a bit line variation/spontaneous polarization.

FIG. 24 illustrates the reason why reduction in a grain size results in reduction of defective bits.

FIG. 25 shows atomic force microscopy photographs (images) of a surface of a PZT film deposited under the following conditions:

(a) a film is formed by forming an initial amorphous layer of PZT in the first process and then growing PZT; and

(b) a film is formed by conducting conventional PTO nucleation and then growing PZT.

FIG. 26 shows X-ray diffraction spectra for a PZT film deposited after forming an initial amorphous layer,

(a) immediately after forming the initial amorphous layer; and

(b) after depositing the PZT film (there are shown not only a spectrum for a film deposited after forming an initial amorphous layer, but also a spectrum for a film deposited by a conventional process).

FIG. 27 shows leak current properties for PZT films deposited under the conditions of

(a) initial amorphous layer formation; and

(b) a conventional process.

FIG. 28 shows an embodiment of a process for manufacturing a device according to this invention.

FIG. 29 shows an embodiment of a process for manufacturing a device according to this invention.

FIG. 30 shows an embodiment of a process for manufacturing a device according to this invention.

FIG. 31 shows an embodiment of a process for manufacturing a device according to this invention.

FIG. 32 shows an embodiment of a process for manufacturing a device according to this invention.

FIG. 33 schematically shows PZT growth according to a conventional process.

FIG. 34 schematically shows nucleus formation.

In these figures, symbols represent the followings; 11: base (Ru) film, 12: crystal nucleus (PTO), 13: polycrystal (PZT) film, 14, 14b: precursor, 191: base (Ru), 192, 192a: precursor, 193: crystal nucleus (PTO), 194: polycrystal (PZT) film, and 195: grain boundary.

### BEST MODE FOR CARRYING OUT THE INVENTION

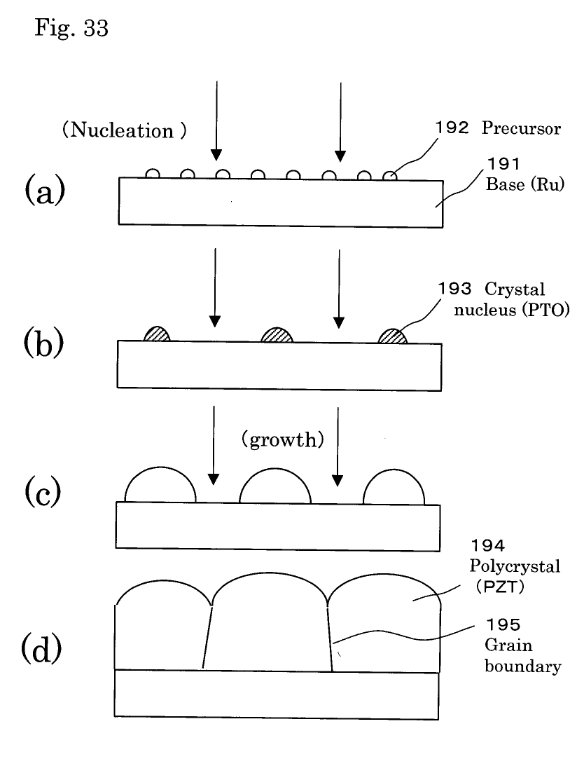

FIG. 33 schematically shows growth of a metal-oxide dielectric PZT polycrystal film 194 on a base conductor (hereinafter, referred to as “base material” or “base film”) Ru film 191 by a deposition process at a low temperature using conventional MOCVD. There will be herein described a case where PTO (lead titanate: PbTiO₃) crystal nuclei 193 are formed under the first deposition conditions using only organometallic source gases of Pb and Ti and an oxidizing gas and then PZT is deposited under the second deposition conditions further using a Zr source gas at the same temperature and the same pressure as described in Japanese Laid-open Patent Publication 2000-58526.

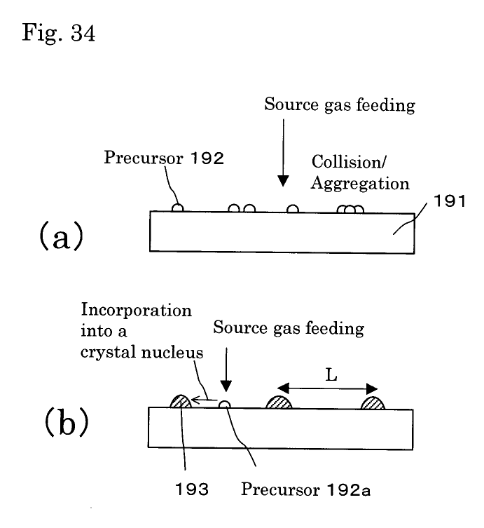

According to our investigation, a conductive oxide film is formed on a surface such as Ru, Ir, RuO₂ and IrO₂, and thus, when forming PTO crystal nuclei 193 on a surface made of a base metal quite inert to a crystal component metal such as Pb, Ti and Zr, there are formed perovskite nuclei with a smaller density than a polycrystal grain of the base metal as shown in FIG. 33 (FIGS. 33(a), (b)). This will be described with reference to FIG. 34. As shown in FIGS. 34(a), (b), a precursors 192 deposited on the surface of a base Ru film 191 migrate by diffusion on the surface to be aggregated by mutual collision to form crystal nuclei 193. A distance L between crystal nuclei 193, therefore, may depend on a surface diffusion distance of the precursor. A precursor 192a deposited on the base surface after formation of crystal nuclei to some degree (FIG. 34(b)) migrates on the surface and are then incorporated into a crystal nucleus 193 within its surface diffusion distance, resulting in crystal nucleus growth.

A perovskite nucleus density at 450° C. is about 1/500 nm-square. When depositing PZT centering the nuclei, a grain size (crystal size) becomes about 500 nm. These perovskite nuclei are randomly oriented so that PZT polycrystal grains have substantially random orientations in the subsequent PZT deposition process. Increase in a grain size of the PZT polycrystal 194 leads to a larger facet and thus a rougher PZT surface (FIGS. 33(c), (d)).

It reduces a distance between the surface and the base metal at the position of the grain boundary 195, leading to a problem of a larger leak current. The thinner the film is, the more significant the problem is. Difficulty in distinguishing an alignment mark through a PZT film thus formed is due to larger irregular reflection on the rougher surface.

After investigation, we have also found that a grain size is involved in variation in a difference of bit-line voltage between capacitive elements associated with integration of a number of memories. Specifically, for a small capacitor, a large grain size results in significant reduction of the number of PZT polycrystal grains in a capacity part, and therefore, variation between polycrystal grains becomes more influential. For example, when a capacitor area is 1 μm² and a PZT grain size is 500 nm, the capacitor contains only several PZT polycrystal grains. In this case, one polycrystal grain inadequately exhibiting a desired property may significantly affect a hysteresis property of the whole capacitor, leading to variation in a bit line voltage distribution.

When all the organometallic source gases constituting a metal-oxide dielectric are used for forming initial nuclei and deposition is then conducted varying a flow rate, adequate flatness cannot be also obtained for a substrate made of, for example, Ru, Ir, RuO₂ or IrO₂.

Thus, in this invention, deposition of a metal-oxide dielectric is divided into the first and the second processes which are conducted under different conditions (the first deposition conditions and the second deposition conditions). In the first process, initial perovskite crystal nuclei or an initial amorphous layer having an amorphous structure are/is formed on a base conductor material, and in the second process, a further perovskite crystal structure film is deposited on the initial crystal nuclei or the initial amorphous layer formed in the first process. The above problem can be solved when the first conditions meet either (a) a lower substrate temperature or (b) a higher pressure than that in the second deposition conditions.

The term “substrate temperature” used herein correctly refers to a temperature of a base conductor on which a metal-oxide dielectric film is deposited, but a “substrate temperature” is used as conventionally used.

There will be described aspects where initial perovskite crystal nuclei are formed and where an initial amorphous layer having an amorphous structure is formed in the first process, separately.

<Aspect Where Initial Nuclei are Formed>

The term “initial nuclei” as used herein refers to both states where crystal nuclei exist as islands and where crystal nucleus islands are aggregated to form a layer. In both cases, deposition is conducted under appropriate conditions to include good crystal nuclei. In the case of forming initial nuclei as a layer, even when forming a metal-oxide dielectric film having a different composition is formed in the second process, the initial nucleus layer is absorbed in a layer formed in the second process so that the initial nucleus layer is not observed, or if observed, it does not affect electric properties of the metal-oxide dielectric film formed in the second process. The term “initial nuclei” as used herein, therefore, encompasses the state where islands are aggregated, but not form a layer. Under usual conditions, it is preferable to stop the first process at the point where initial nuclei exist as islands, in the light of controllability. In both islands and a layer, a thickness of the initial nuclei is generally 5 nm or less, preferably 3 nm or less and 1 nm or more.

In this aspect, when employing the first deposition conditions where (a) a substrate temperature is lower than that in the second deposition conditions or (b) a pressure is higher than that in the second deposition conditions to form initial nuclei, a final metal-oxide dielectric film has a reduced grain size, resulting in reduced surface irregularity. In the description below or the appended drawings, the process employing the condition (a) or (b) may be sometimes called “low-temperature initial nucleation” or “high-pressure initial nucleation”.

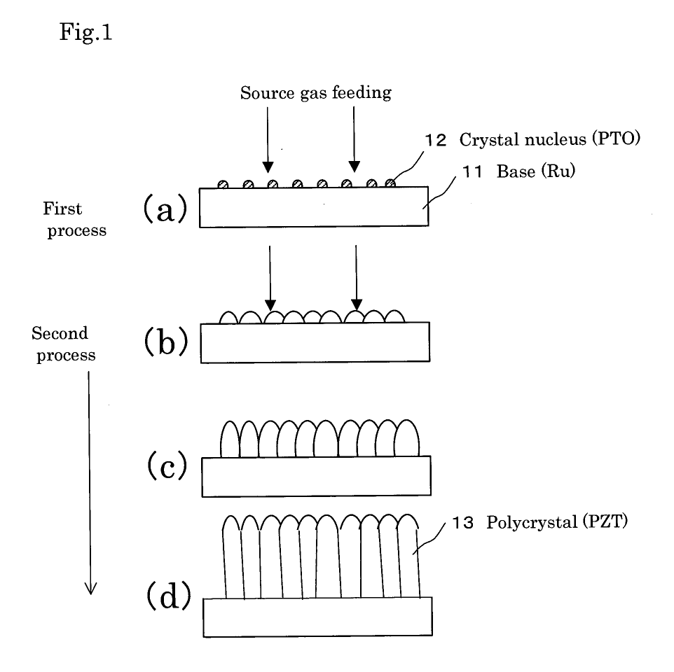

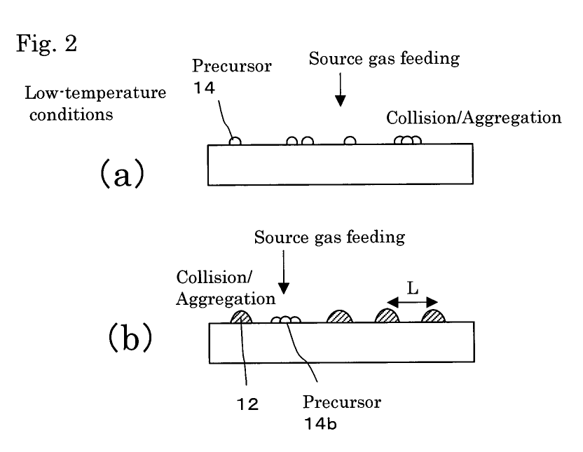

There will be schematically described an embodiment of this invention where a PZT polycrystal is deposited on a Ru film (base metal film) by first forming PTO (lead titanate: PbTiO₃) crystal nuclei under the first deposition conditions and then depositing PZT under the second deposition conditions, with reference to FIG. 1. FIG. 1(a) shows nucleus formation on the surface of the base Ru film 11 in the first process. When a nucleus formation temperature is lower than that in the second deposition conditions or a nucleus formation pressure is higher, a density of crystal nuclei 12 is higher than that for nucleus formation under the second deposition conditions in the second process. FIG. 2 shows nucleus formation.

FIG. 2 schematically shows deposition under the first conditions employing a low temperature. As shown in FIGS. 2(a), (b), crystal nuclei 12 may be formed by mutual collision and aggregation of precursors 14 on the base surface as in the above mechanism 2, but a surface diffusion distance is reduced at a low temperature so that a distance contributing collision/aggregation is reduced, leading to a shorter distance L between crystal nuclei. As shown in FIG. 2(a), when precursors 14b are deposited on the base surface after forming crystal nuclei to some degree, a precursor is aggregated by collision with a subsequently deposited precursor in the vicinity, if no crystal nuclei exist within a given range, to form a new crystal nucleus even in the case where the precursor might be absorbed into a near crystal nucleus at a high temperature, because a surface diffusion distance is reduced at a low temperature. Thus, a nucleus density is increased in low-temperature nucleation.

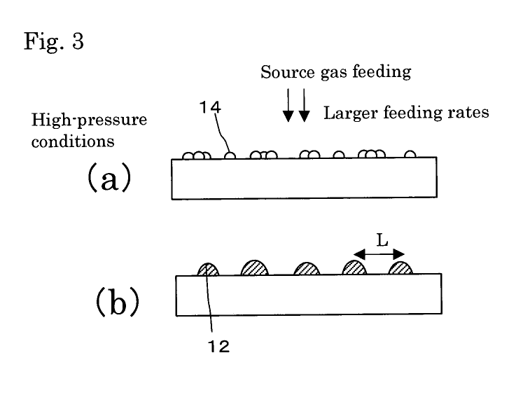

FIG. 3 schematically shows deposition under the first conditions employing a high pressure. Crystal nuclei 12 are formed by mutual collision/aggregation of precursors 14 on the base surface as described above. However, as shown in FIG. 3(a), when a large amount of materials are fed, there exists a large amount of gases near the surface and the precursors 14 more frequently collide so that a substantial surface diffusion distance is reduced. Neighboring precursors are quickly aggregated by collision to form crystal nuclei 12, whose positions are fixed, so that a distance L between crystal nuclei is reduced, resulting in an increased nucleus density.

FIG. 1(b) shows the initial stage of deposition under the second deposition conditions during the second process. As seen in this figure, once PTO crystal nuclei are formed, migration on the surface is reduced so that a nucleus density does not vary even when a temperature is elevated. When subsequently depositing PZT, PZT polycrystals 13 are grown with their small grain size being maintained because a nucleus density has been increased (FIG. 1(c)). As a result, flatness of the surface of a resulting PZT film is improved as shown in FIG. 1(d).

As will be described later, the second deposition conditions employed in the second process correspond to those in a usual deposition process, and there is, therefore, a preferable range in the light of crystallinity. If both first process (nucleation) and second process (deposition) are conducted at a low temperature, for example, in the above case, since crystallization temperature for PZT is higher than that for PTO, deterioration in crystallinity of the film or formation of an amorphous film is observed, leading poor electric properties such as inadequate polarization. If both first and second processes are conducted at a high pressure, a surface diffusion distance of precursors during the second process as main deposition might become shorter and they could not reach correct grid positions, leading to deteriorated crystallinity.

<Conditions for Low-Temperature Nucleation>

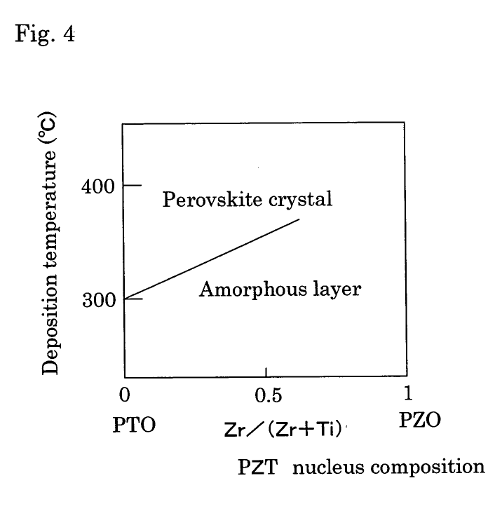

When controlling a grain size mainly by low-temperature nucleation, a substrate temperature (i.e., a temperature of a base conductor material) during nucleus formation (i.e., the first process) is generally 350 to 450° C., preferably 370° C. or higher and 400° C. or lower. The lower limit of a temperature in the first process is restricted by a temperature at which crystal nuclei generate. The temperature also depends on a composition for nucleus formation. When depositing a PZT film, nucleation can be initiated at a low temperature using a composition with a smaller rate of Zr, as schematically shown in FIG. 4. Generally, a temperature allowing good crystallization is about 350° C. or higher, and a temperature of 370° C. or higher may provide crystals with adequate crystallinity for being used as nuclei. The upper limit of a nucleation temperature depends on leak resistance and processability required to a dielectric film. Conditions are preferably selected such that a grain size becomes about 150 nm or less, in the sense that alignment in lithography can be conducted without any problem. Such conditions may be met when nucleation is conducted at 400° C. or lower.

Even when a period of the first process is very short, source gases and an oxidizing gas may be concurrently fed to correspondingly reduce irregularity of a metal-oxide dielectric film deposited. However, when the first process is too long, a PbO film may be deposited because a large amount of Pb has been fed during the first process. Thus, the conditions including a period are limited to those before PbO film formation. A period before PbO film formation varies depending on the conditions and may be readily determined experimentally by X-ray diffraction. The period is generally 60 sec or less, preferably 3 to 20 sec.

A substrate temperature (i.e., a temperature of a base conductor material) during main deposition (i.e., the second process) is generally 400 to 700° C., preferably 400° C. or higher and 470° C. or lower, particularly 450° C. or less. A substrate temperature in the second process is higher than that in the first process. In terms of a temperature in the second process, in common chemical vapor deposition, a higher temperature may generate larger polarization and therefore a larger capacity while tending to increase a leak current. The leak current is, however, reduced by applying this invention. When forming a metal-oxide dielectric film on a substrate in which an aluminum interconnection has been formed in a practical semiconductor device, the second process is preferably conducted at 450° C. or lower, taking heat resistance of the aluminum interconnection into account.

The most preferable temperature conditions are, therefore, nucleation at 370 to 400° C. and then deposition after heating to 400 to 450° C.

A source gas pressure in the first process is preferably 100 Torr (13.3 kPa) or less, for example 20 Torr (2.67 kPa) or less because an excessively higher pressure may inhibit crystallization. In the second process, it is preferably 1 Torr (133 Pa) or less, particularly 200 mTorr (26.7 Pa) or less because an excessively higher pressure may deteriorate crystallinity. Since film deposition does not proceed at a too lower pressure, a practical pressure in both first and second processes is preferably 1×10⁻⁴ Torr (1.33×10⁻² Pa) or more.

<Conditions for High-Pressure Nucleation>

When controlling a grain size mainly by high-pressure nucleation (i.e., in the first process), a source gas pressure is 0.1 to 100 Torr (13.3 Pa to 13.3 kPa), preferably 1 Torr (133 Pa) or higher and 20 Torr (2.67 kPa) or lower. A source gas pressure in the second process is preferably 1 Torr (133 Pa) or lower, particularly 200 mTorr (26.7 Pa) or lower because an excessively higher pressure may deteriorate crystallinity. Since film deposition does not proceed at a too lower pressure, a practical pressure is preferably 1×10⁻⁴ Torr (1.33×10⁻² Pa) or higher. Within this range, a pressure in the first deposition conditions is selected to be higher than that in the second deposition conditions.

A substrate temperature is preferably 350 to 700° C. in the first deposition conditions and 400 to 700° C. in the second deposition conditions.

<Common Conditions in Low-Temperature Nucleation and High-Pressure Nucleation>

Although there have been described low-temperature and high-pressure nucleation techniques separately, practical production is preferably conducted in the light of process simplification such that the first deposition conditions meet one of the following requirements:

(1) a lower substrate temperature and the same pressure;

(2) the same substrate temperature and a higher pressure; and

(3) a lower substrate temperature and a higher pressure, in comparison with the second deposition conditions. When employing both low-temperature and high-pressure nucleation techniques (the above requirement (3)), the conditions may be determined to meet these requirements.

A nucleation mechanism in a surface reaction in CVD is as described above, but some parameters such as a surface diffusion rate for a precursor are little understood in a practical system. However, a grain size of a polycrystal film deposited varying a temperature and a pressure may be observed by, for example, SEM to allow us to easily determine conditions which provide an optimal grain size and optimal surface flatness.

A base conductor material used in this aspect may be any material as long as it can be used as a base film for an oxide dielectric film such as PZT (including the case where a base is directly a substrate). This invention is particularly effective when using Ru, Ir, RuO₂ or IrO₂ which gives insufficient electric properties or processability in a conventional process. A particularly preferable base conductor material is Ru. “Using a Ru substrate” herein include a case where the uppermost surface of the substrate is oxidized during nucleation and/or deposition to form a RuO₂ layer.

In practical deposition, the base material may be a monolayer or multilayer film. When applying this invention to formation of a capacitor film, a multilayer film is often formed for various reasons in a practical semiconductor device. In either case, any of the above materials can be used as a base material for forming a metal oxide dielectric film. When forming a multilayer structure using Ru as a base material, a lower layer may be appropriately selected. In a Ru/Ti/TiN/Ti structure where TiN and Ti are deposited on Ti, the TiN layer acts as a barrier for preventing oxidation of a plug or interconnection in the base. The intermediate sandwiched Ti layer is an adhesion layer for preventing peeling. A Ru/Ti/TiN/Ti/W structure where a W layer is formed in the layers of the above structure is more preferable.

Examples of a metal oxide dielectric represented by ABO₃ having a perovskite type crystal structure deposited by a process according to this invention include, besides a PZT, STO [SrTiO₃], BTO [BaTiO₃], BST [(Ba,Sr)TiO₃], PTO [PbTiO₃], PLT [(Pb,La)TiO₃], PLZT [(Pb,La) (Zr,Ti)O₃], PNbT [(Pb,Nb)TiO₃], PNbZT [(Pb,Nb)(Zr,Ti)03], and one of the above Zr-containing metal oxides in which Zr is replaced with at least one of Hf, Mn and Ni.

In this invention, constituting metal elements may be derived from their organometallic compounds. A PZT film may be, for example, formed from lead bis(dipivaloyl)methanate (Pb(DPM)₂) as a Pb source, zirconium butoxide (Zr(OtBu)₄) as a Zr source and titanium isopropoxide (Ti(OiPr)₄) as a Ti source. A BST film may be, for example, formed from barium bis(dipivaloyl)methanate (Ba(DPM)₂), strontium bis(dipivaloyl)methanate (Sr(DPM)₂) and titanium tetraisopropoxide (Ti(OiPr)₄) gases.

In addition to organometallic source gases, an oxidizing gas is preferably used for fully oxidizing the organometallic source gases on a surface without oxygen deficiency for preventing these gases from forming an alloy on a base conductor material. Examples of an oxidizing gas include nitrogen dioxide, ozone, oxygen, oxygen ions and oxygen radicals. Nitrogen oxide is particularly preferable because of its strong oxidizing power.

When feeding these source gases into a chamber of a CVD apparatus, each gas flow may be controlled by a mass flow controller without using a carrier gas (solid sublimation method). Alternatively, an organometallic material dissolved in a solvent such as butyl acetate and tetrahydrofuran may be transferred as a liquid, vaporized in a vaporizing chamber near a deposition chamber and then fed together with a carrier gas such as nitrogen (liquid transfer method). A source gas pressure herein means a gas pressure after subtracting partial pressures of components not involved in a reaction such as a carrier gas and a solvent.

A pressure may be most effectively varied by controlling an exhaust volume by means of altering a cross-sectional area of an exhaust hole. Such variation of an exhaust volume can increase source gas concentrations charged to a substrate surface without changing the whole gas ratio.

It is known in a reduced-pressure thermal CVD process at about 1 Torr or lower of the total source gas pressure during deposition, that there exist composition self-adjusting conditions where a composition ratio of elements A and B in an ABO₃ type crystal is adjusted to a stoichiometric ratio within a given range of a source gas flow rate. Under these conditions, reproductivity and uniformity of deposition may be improved and a film formed may exhibit excellent electric properties. The second process in this invention is, therefore, conducted under such self-adjusting conditions, and such self adjustment can occur at a substrate temperature of 400° C. or higher while a pressure is 1 Torr (133 Pa) or lower, particularly 200 mTorr (26.7 Pa) or lower.

In this invention, the first and the second deposition conditions are different at least in a substrate temperature and a source gas pressure. It is preferable that the other deposition conditions are varied to be individually optimized. Deposition under such conditions may provide a film exhibiting excellent orientation, crystallinity, inversion fatigue, surface flatness and leak properties.

In terms of altering deposition conditions other than a substrate temperature and a source gas pressure, deposition may be conducted varying feeding conditions of organometallic material gases.

Examples include (i) a process where all the organometallic material gases as materials for a metal-oxide dielectric are used under the first deposition conditions to form initial nuclei of a crystal having a perovskite crystal structure on the above base conductor material and then under the second deposition conditions, a further film of a perovskite crystal structure is grown over the initial crystal nuclei, and (ii) a process where only a portion of the organometallic source gases to be materials for a metal-oxide dielectric are used under the first deposition conditions to form initial nuclei of a perovskite crystal on the base conductor material and a film having a perovskite crystal structure is further grown over the initial nuclei under the second deposition conditions.

For deposition of PZT, in the above process (i), deposition is conducted using, for example, Pb, Zr and Ti source gases in both first and second deposition processes while changing flow rates. In the above process (ii), Pb and Ti source gases are used in the first deposition process while Pb, Zr and Ti source gases are used in the second deposition process. As in this example, it is preferable in the process (ii) that both element A and element B source gases for an ABO₃ perovskite crystal are contained.

It is also preferable that while the second deposition conditions involve feeding source gases with good self-controllability, the first deposition conditions involve feeding an element A source in a larger amount than that in the second deposition conditions.

When using both Zr and Ti as an element B, it is also preferable that deposition is conducted with a smaller ratio of a Zr source /a Ti source in the first deposition conditions than in the second deposition conditions.

When using Zr and another element as an element B, it is also preferable that deposition under the first deposition conditions is conducted without feeding a Zr source gas.

By the low-temperature or high-pressure method as described above, a grain size may be reduced and therefore, when applying a device to a capacitive element, a leak current may be reduced, variation in a bit line voltage difference between capacitors, an yield may be improved because of minimizing defective bits and alignment may be easily performed without film opacifying.

According to the prior art, depositing PZT on the surface of an Ir, Ru, IrO₂ or RuO₂ base material provides a film with a grain size of 300 nm or more. In contrast, a manufacturing process according to this invention can deposit a PZT film having a grain size of 50 nm to 200 nm. In other words, a PZT film having a grain size within a range of 50 nm to 200 nm which is deposited on the surface of a base conductor material selected from the group consisting of Ir, Ru, IrO₂ and RuO₂ is an unknown novel film.

<Aspect Where an Initial Amorphous Layer is Formed>

There will be described formation of an initial amorphous layer in the first process.

As described in Examples later, forming an initial amorphous layer in the first process and then conducting main film deposition in the second process may give a similar grain size to that obtained using the same temperature/pressure conditions in the first and the second processes as in a conventional method, but an orientation is changed to (110) so that a facet formed in a crystal grain surface becomes parallel to the substrate, resulting in a flat surface. As a result, when applying a device to a capacitive element, a leak current is reduced and alignment is easily performed without film opacifying.

The initial amorphous layer deposited in the first process is such a layer that it may finally become unrecognizable as an amorphous layer since crystallization takes place simultaneously during main deposition in the second process. Since a too thick layer does not give good crystal nuclei, a thickness of the initial amorphous layer is preferably about 1 to 5 nm, particularly about 1 to 3 nm.

Even if a period of the first process is very short, as long as source gases and an oxidizing gas are concurrently fed, it correspondingly reduces irregularity of a metal-oxide dielectric film deposited. However, if the first process is too long, satisfactory crystal nuclei cannot be formed, leading to deteriorated crystallinity of polycrystal deposited in the second process. Thus, the conditions including a period are limited to those before such deterioration occurs. A period before deterioration in crystallinity of a polycrystal layer varies depending on the conditions and may be readily determined experimentally by X-ray diffraction. The period is generally 60 sec or less, preferably 3 to 20 sec.

In this aspect, the first deposition conditions are determined so as to form an initial amorphous layer in the first process while at least one of the requirements (a) a lower substrate temperature than that in the second deposition conditions and (b) a higher source gas pressure than that in the second deposition conditions is fullfilled. It is particularly preferable that the first deposition conditions meet the requirement (a) a lower substrate temperature than that in the second deposition conditions. As shown in FIG. 4, an amorphous layer can be formed by low-temperature deposition, and for PZT deposition, a very low temperature is not necessary by feeding source gases having a composition containing Zr to some extent under the first conditions. It is also, therefore, preferable for forming an initial amorphous layer that the same flow rates for source gases are used in the first and the second processes.

When forming an initial amorphous layer at a low temperature of the requirement (a), a substrate temperature is selected within a range that source gases are decomposed and an amorphous layer is formed. For example, the temperature is preferably 300 to 350° C., particularly 320 to 340° C. A pressure in the first process, all the conditions in the second process, the other deposition conditions and all the other conditions such as materials used are as described in “Aspects where initial nuclei are formed”. When forming an initial amorphous layer at a high-pressure, all of these conditions are as described in the section of <Aspect where initial nuclei are formed>.

### EXAMPLES

This invention will be more specifically described with reference to Examples.

### Example of Low-Temperature Nucleation

On a 6 inch silicon wafer as a substrate was formed a base metal layer having a Ru (100 nm)/SiO₂ structure by sputtering. The Ru film may be deposited by MOCVD. Source gases were Pb(DPM)₂ as a Pb source, Zr(OtBu)₄ as a Zr source, Ti(OiPr)₄ as a Ti source and NO₂ as an oxidizing agent. Each gas flow rate was controlled by a mass flow controller without using a carrier gas. A pressure during growth was 5×10⁻³ Torr (6.6 Pa). PZT was deposited by first forming island PTO nuclei (initial crystal nuclei) with a size of 3 to 5 nm under the first conditions at a low temperature and PZT is then deposited under the second conditions at a high temperature. In the first process, onto a Ru base metal film were fed Pb(DPM)₂ at 0.2 sccm, Ti(OiPr)₄ at 0.25 sccm and NO₂ at 3.0 sccm for nucleation. In the second process, deposition was conducted by feeding Pb(DPM)₂ at 0.25 sccm, Zr(OtBu)₄ at 0.225 sccm, Ti(OiPr)₄ at 0.2 sccm, NO₂ at 3.0 sccm and N₂ at 150 sccm. An upper electrode was also made of Ru. After forming the upper electrode, recovery annealing was conducted at 400° C. for 10 min.

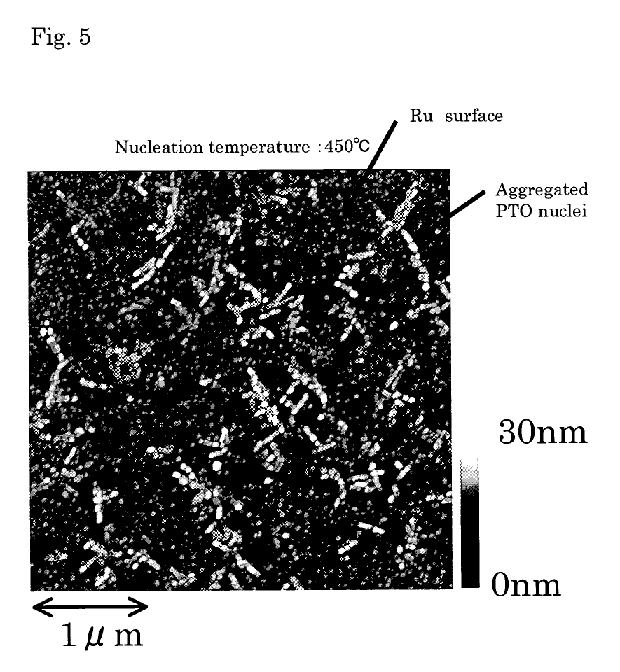

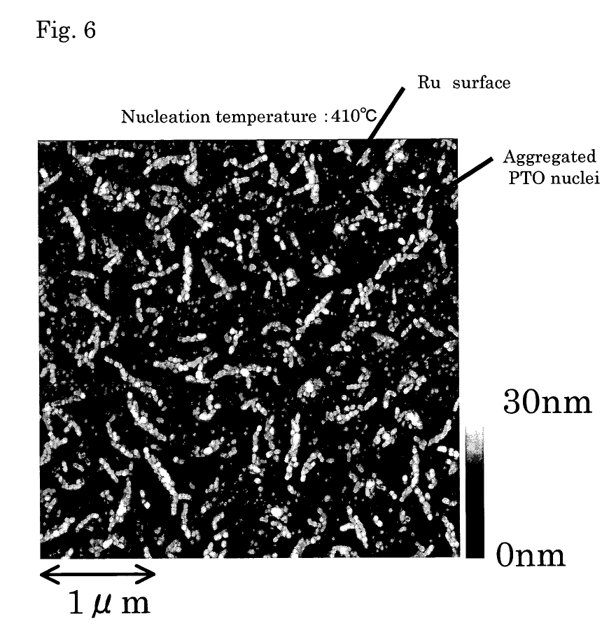

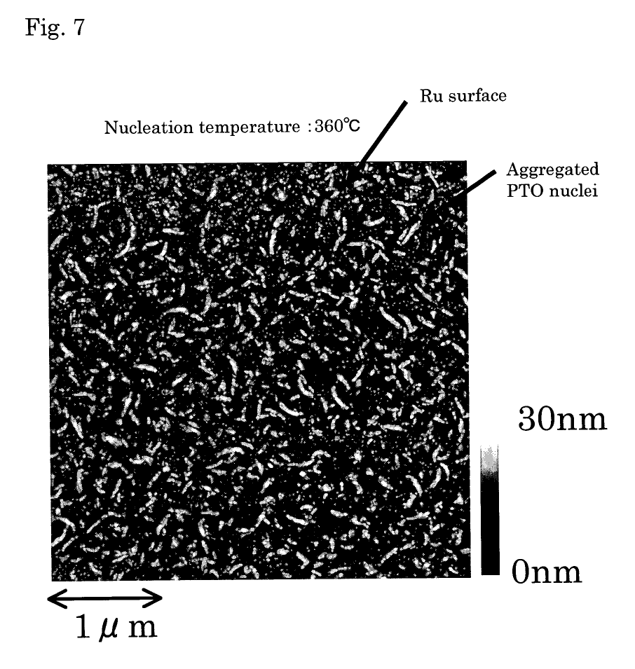

First, Pb(DPM)₂, Ti(OiPr)₄ and NO₂ were simultaneously fed to the Ru base metal film while varying a substrate temperature, and then crystal nuclei of perovskite lead titanate on the Ru surface was observed by atomic force microscopy (AFM). The results are shown in FIGS. 5 to 7. FIGS. 5 to 7 show nucleation at substrate temperatures of 450° C., 410° C. and 360° C., respectively. Crystal nuclei of lead titanate are observed as a rodlike group in which microcrystals are lined. Its density is 2 groups/μm² on the average in FIG. 5 while being 5 groups/μm² and 12 groups/μm² in FIGS. 6 and 7, respectively. It indicates that reduction in a substrate temperature in nucleation increases a crystal nucleus density.

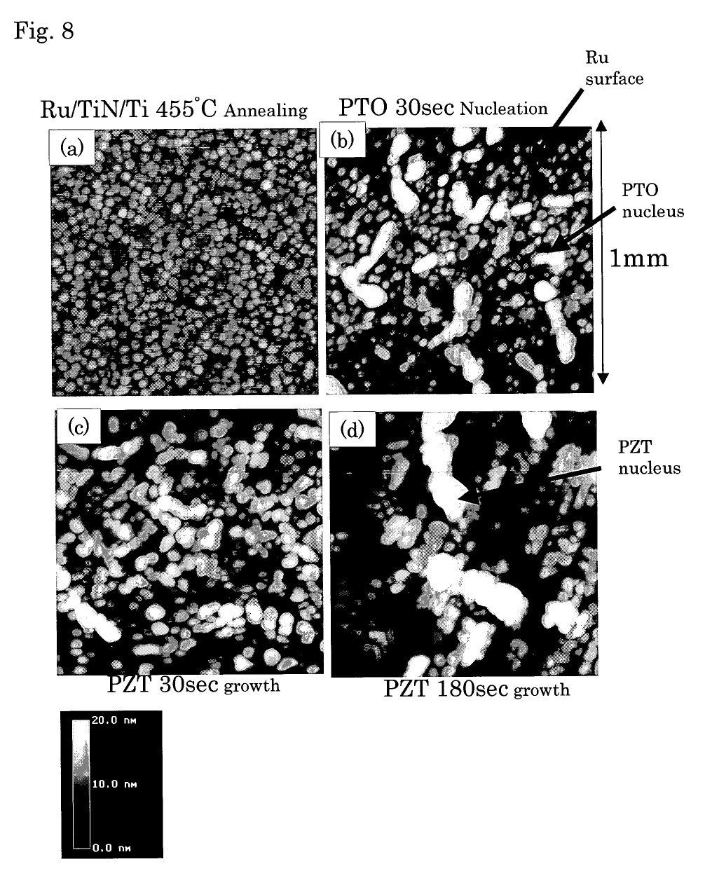

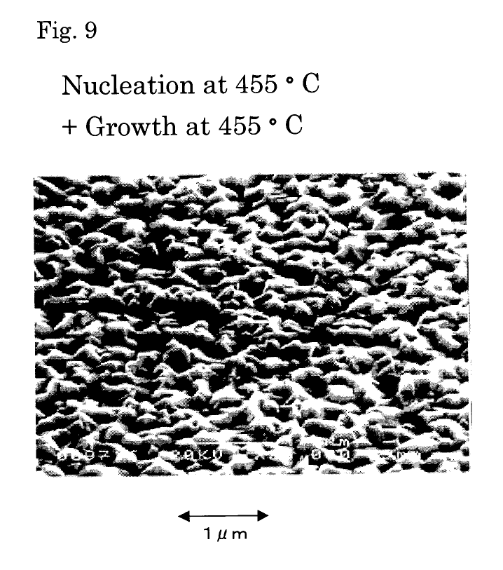

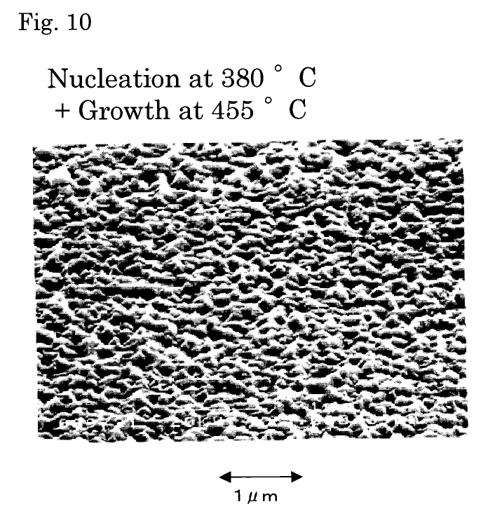

FIG. 8 shows observation of a deposition process for a PZT by atomic force microscopy in sequence. Specifically, FIG. 8(a) shows a Ru surface heated at 450° C. As shown in FIG. 8(b), rodlike nuclei are observed after forming initial crystal nuclei of PTO for 30 sec. After depositing PZT for 30 sec (FIG. 8(c)) and then continuing PZT deposition for further 60 sec (FIG. 8(d)), it is indicated that a polycrystal grain density is little changed and the PZT polycrystals were formed keeping a density of the initial crystal nuclei constant, FIGS. 9 and 10 show the surface after depositing the PZT film to 250 nm by scanning electron microscopy (SEM). A deposition temperature of PZT was constant at 455° C. FIGS. 9 and 10 show the cases where a PTO nucleation temperature is 455° C., i.e., equal to the PZT deposition temperature and 380° C., i.e., lower than the PZT deposition temperature, respectively. It can be clearly observed that a lower initial nucleation temperature of PTO crystals results in reduced irregularity in the surface of the PZT deposited thereon.

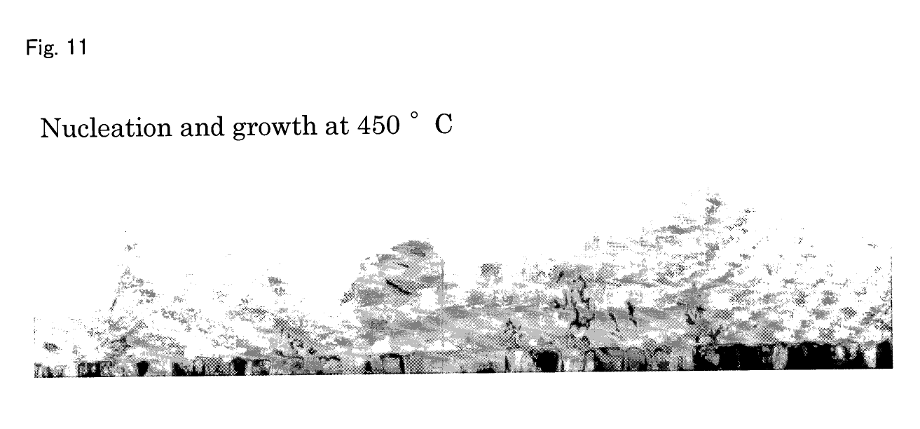

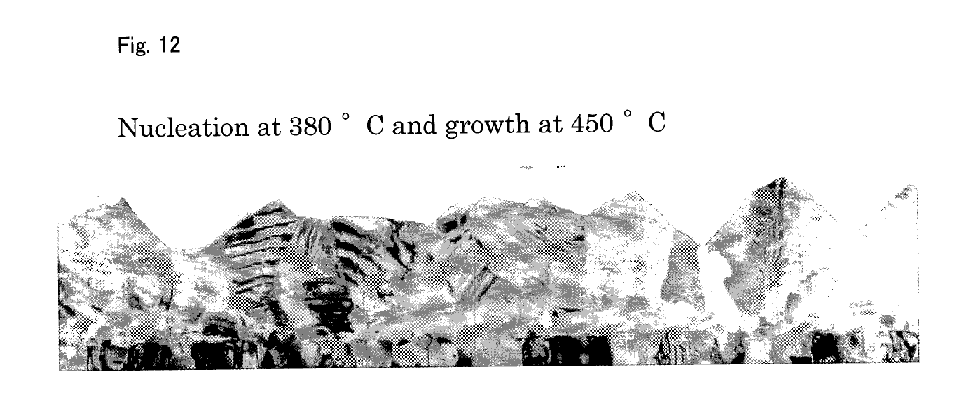

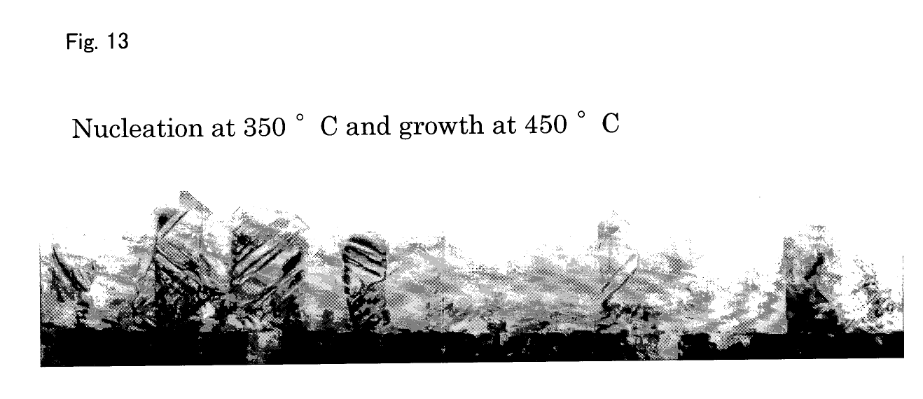

FIGS. 11 to 13 show the surface after depositing the PZT film to 250 nm by cross-sectional transmission electron microscopy (TEM). A deposition temperature of PZT was constant at 455° C. FIGS. 11 to 13 show the cases where a PTO nucleation temperature is 455° C, i.e., equal to the PZT deposition temperature, 380° C. and 350° C., respectively. It can be clearly observed that a lower initial nucleation temperature of PTO crystals reduces a PZT grain size, resulting in reduced irregularity in the surface of the PZT.

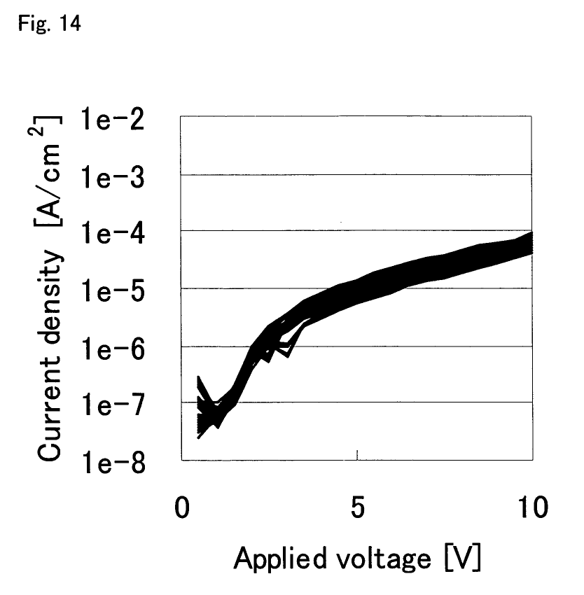

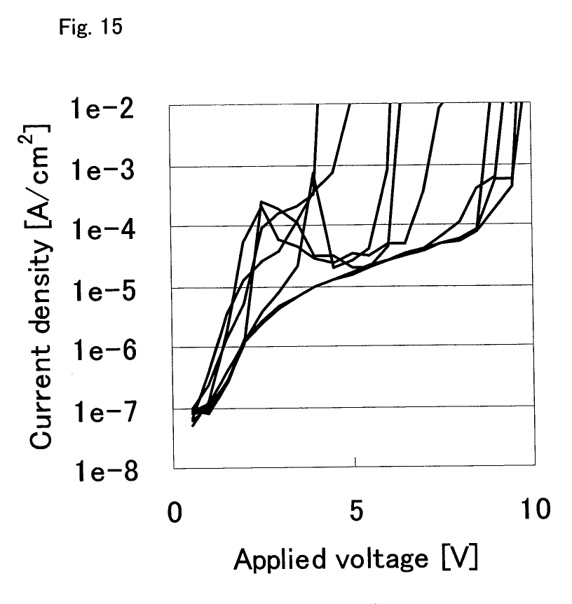

FIG. 14 shows IV properties when initial crystal nuclei of PTO were preformed at a substrate temperature of 380° C. before depositing a PZT film to 250 nm at a substrate temperature of 455° C. A leak current was as good as 10⁻⁴ A/cm² or less at 10 V. In contrast, IV properties when initial crystal nuclei of PTO were formed at the same temperature as PZT deposition, 455° C., shown in FIG. 15 indicate that a current sharply increased in the range of 5 to 8 V. From these results, it has been confirmed that formation of initial crystal nuclei at a low temperature can produce a definite improvement in a leak current.

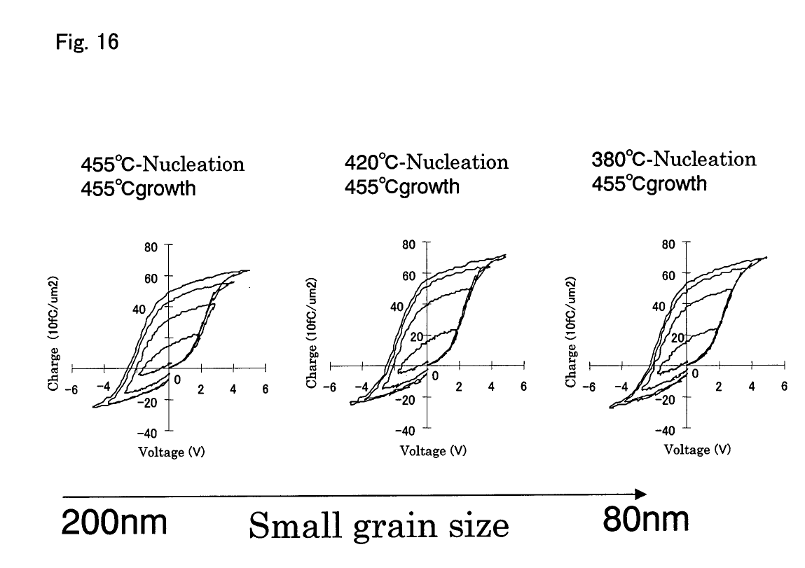

FIG. 16 shows hysteresis property when initial crystal nuclei of PTO were formed varying a substrate temperature in depositing a PZT film to 250 nm at a substrate temperature of 455° C. (the loops in each graph are hysteresis loops when applying voltages of ±2, 3, 4 and 5 from the small size). Even at a low initial nucleation temperature of 380° C., a capacitor obtained shows good hysteresis property with an adequate polarization value (2 Pr value). By employing low-temperature nucleation, a grain size was reduced from 200 nm to 80 nm. Here, the grain size was calculated by averaging polycrystal sizes in a 5×5 μm photograph observed by atomic force microscopy.

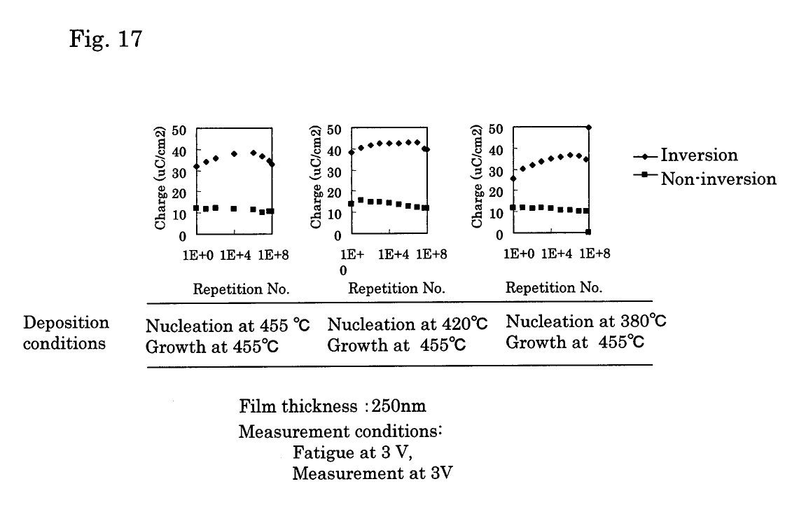

FIG. 17 shows fatigue property at 3V for the same samples, where measurement was also conducted at 3V. It indicates good fatigue property substantially without change in an inversion charge to 1×10⁸ cycles.

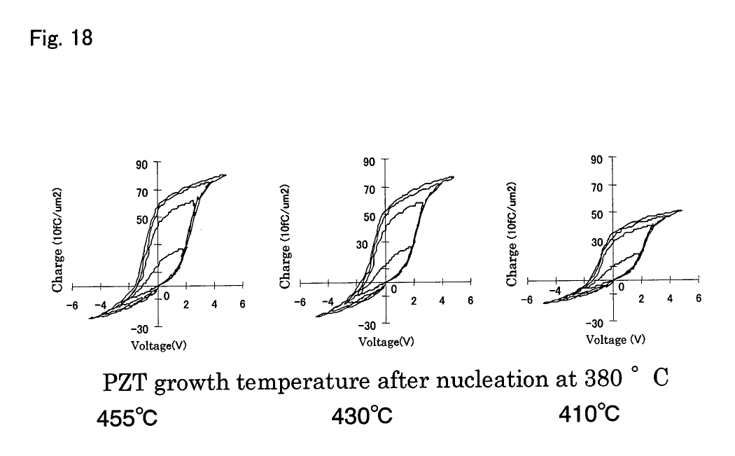

FIG. 18 shows hysteresis property when in depositing a PZT film to 250 nm, initial crystal nuclei of PTO were formed at a constant temperature of 380° C. and a PZT deposition temperature was reduced from 455° C. to 410° C. It indicates that the PZT deposition temperature has a significant effect on hysteresis property and at a deposition temperature of 410° C. or lower hysteresis property is rapidly deteriorated. In other words, it is clear that desired hysteresis property cannot be achieved when a PZT deposition temperature is also reduced to an initial nucleation temperature of 380° C. It, therefore, indicates effects of the characteristic of this invention that the temperature during PZT deposition and the temperature during initial crystal nucleation are set differently.

### Example of High-Pressure Nucleation

An experiment was conducted as described in <Example of low-temperature nucleation>except that PZT deposition conditions were modified. In the first process, onto a Ru base metal film were fed Pb(DPM)₂ at 0.2 sccm, Ti(OiPr)₄ at 0.25 sccm and NO₂ at 3.0 sccm for nucleation. In the second process, deposition was conducted by feeding Pb(DPM)₂ at 0.25 sccm, Zr(OtBu)₄ at 0.225 sccm, Ti(OiPr)₄ at 0.2 sccm, NO₂ at 3.0 sccm and N₂ at 150 sccm. In this experiment, a substrate temperature was constant at 430° C. in the first and the second deposition conditions, and a pressure was controlled by varying an exhaust volume.

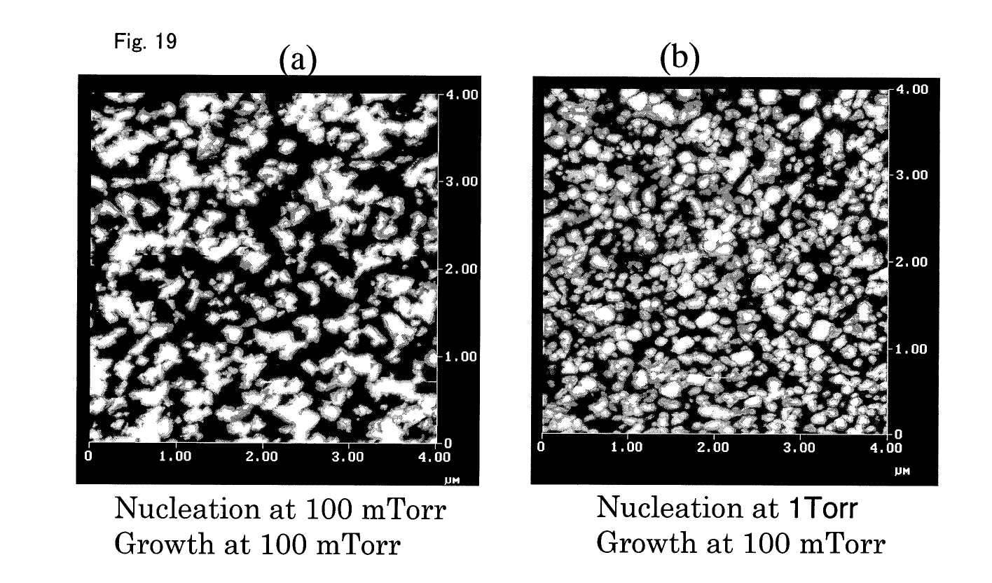

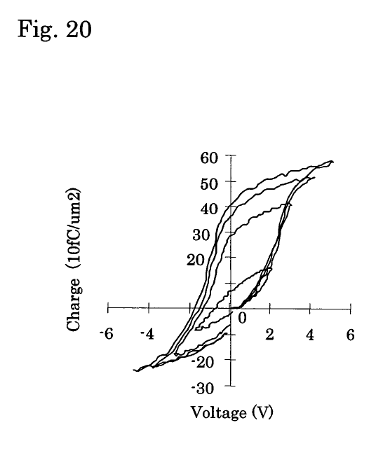

FIGS. 19(a) and (b) show atomic force microscopy (AFM) images of a surface after nucleation in the first process at pressures of 0.1 Torr (13.3 Pa) and 1 Torr (133 Pa), respectively for 30 sec and at 0.1 Torr (13.3 Pa) in the second process to deposit a PZT film to 250 nm. A grain size was 300 nm for the film in FIG. 19(a) at a nucleation pressure of 0.1 Torr while being 80 nm for the film in FIG. 19(b) at a nucleation pressure of 1 Torr. FIG. 20 shows polarization hysteresis property when nucleation was conducted at a high pressure of 1 Torr, indicating satisfactory property.

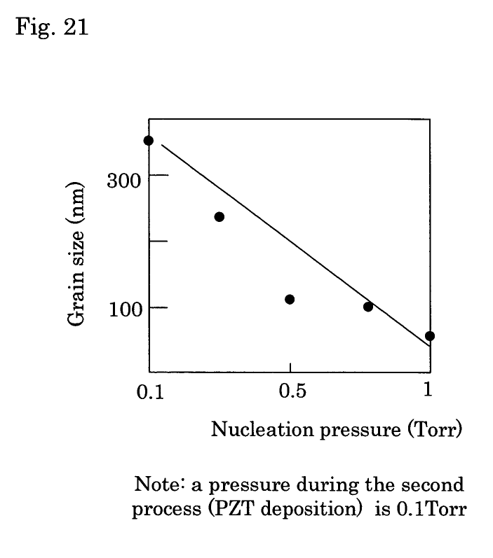

FIG. 21 shows relationship between a pressure and a grain size when varying a pressure in the first deposition conditions, where a pressure in the second deposition conditions is 0.1 Torr.

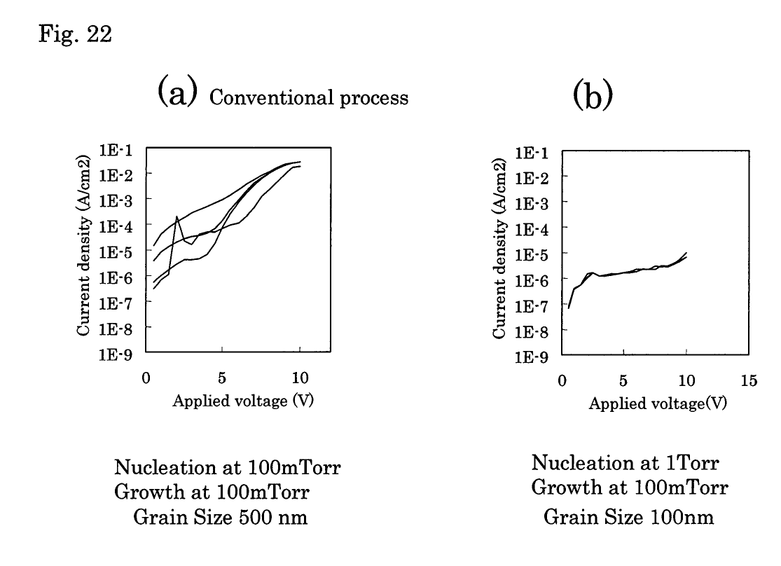

The IV properties in FIGS. 22(a), (b) indicate that a smaller grain size after high-pressure nucleation significantly improved current leak.

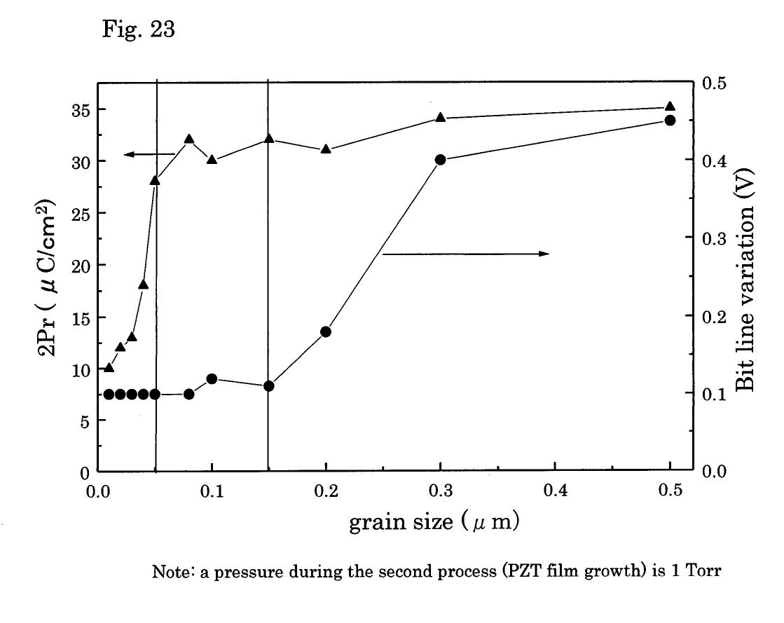

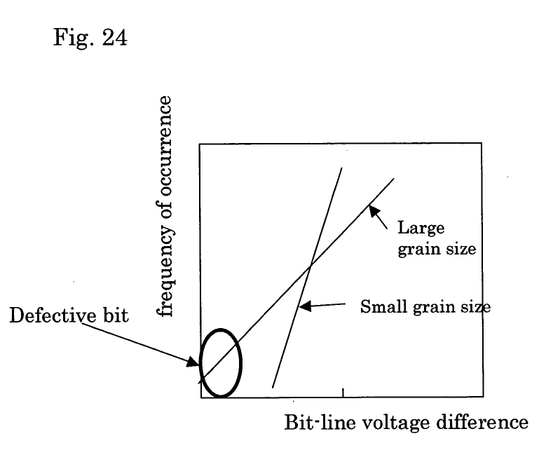

FIG. 23 shows relationship between a grain size and a bit line variation/self-polarization. This figure clearly indicates that bit line variation was improved with a grain size of less than 300 nm, particularly 200 nm or less. It may be probably because reduction in grain size might make a distribution in a bit-line voltage difference narrower, resulting in reduction of defective bits with a small bit-line voltage difference. Furthermore, it is also indicated that a grain size is preferably within a range of 50 nm to 200 nm since a too small grain size leads to reduction in spontaneous polarization.

### Example of the Aspect Where an Initial Amorphous Layer is Formed

An experiment was conducted as described in <Example of low-temperature nucleation>except that PZT deposition conditions were modified. In the first process, onto a Ru base metal film were fed Pb(DPM)₂ at 0.2 sccm, Zr(OtBu)₄ at 0.225 sccm, Ti(OiPr)₄ at 0.25 sccm, NO₂ at 3.0 sccm and N₂ at 150 sccm, and in the second process, these were fed at the same flow rates. In this experiment, while a pressure was 0.1 Torr (13.3 Pa) in both first and second processes, deposition was conducted at a substrate temperature of 330° C. for forming an amorphous layer for 30 sec in the first process and a PZT film was deposited to 250 nm at 430° C. in the second process.

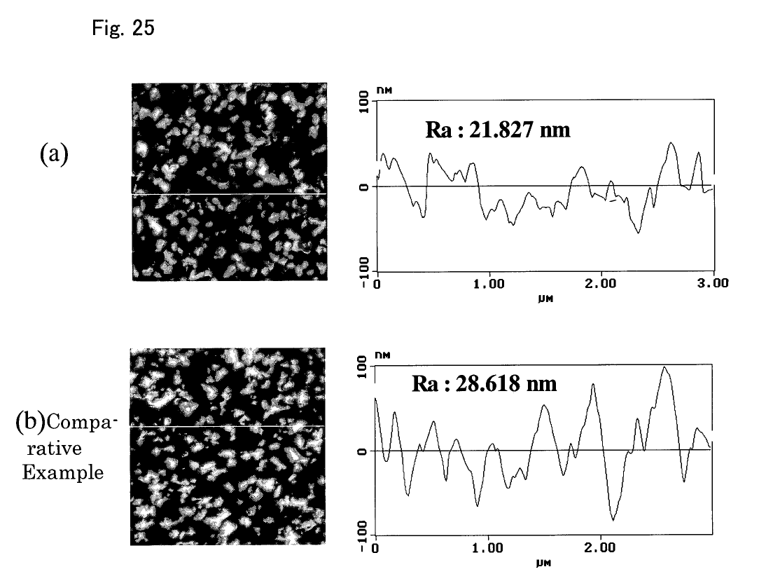

FIG. 25(a) shows an atomic force microscopy (AFM) image of the surface of the deposited film. For comparison, PTO nucleation was conducted at 430° C. in the first process and PZT was deposited at 430° C. in the second process (hereinafter, referred to as “Comparative Example”), and its AFM image is shown in FIG. 25(b). As seen these figures, the film after forming the initial amorphous layer exhibits significant improvement in surface flatness.

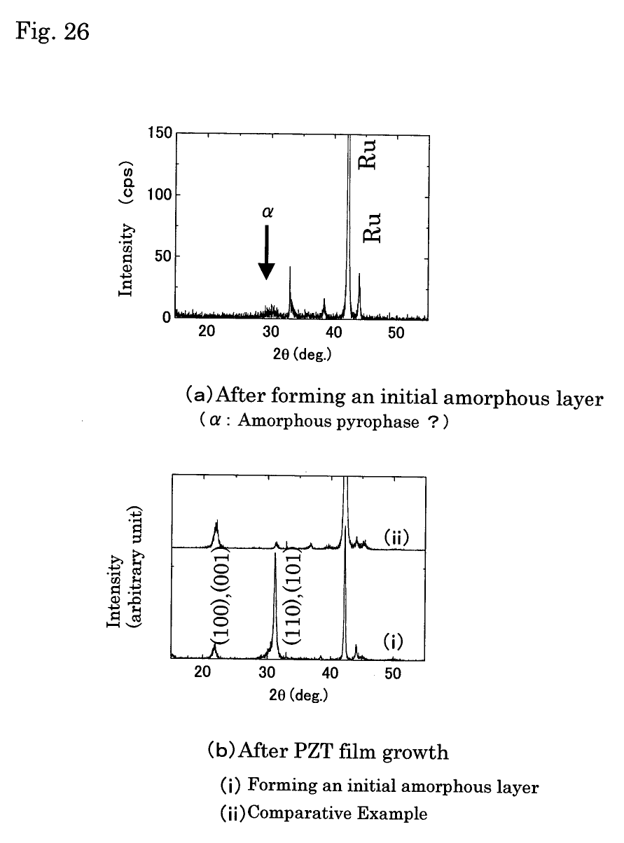

FIG. 26 show X-ray spectra (a) after forming an initial amorphous layer and (b) at the end of PZT film deposition. As shown in FIG. 26(a), no PZT crystal peaks are observed, but instead, a broad peak probably corresponding to an amorphous layer is observed. At the end of deposition as shown in spectrum (i) in FIG. 26(b), (110) and (101) peaks are observed, indicating a crystal orientation different from that in Comparative Example shown in spectrum (ii). That is, it can be speculated that orientation was changed to increase facets parallel to the substrate, resulting in improvement in surface flatness.

Hysteresis property for spontaneous polarization was equivalent to that obtained by a conventional process, and a 2 Pr value measured at a maximum applied voltage of 5 V was 37.21 μC/cm².

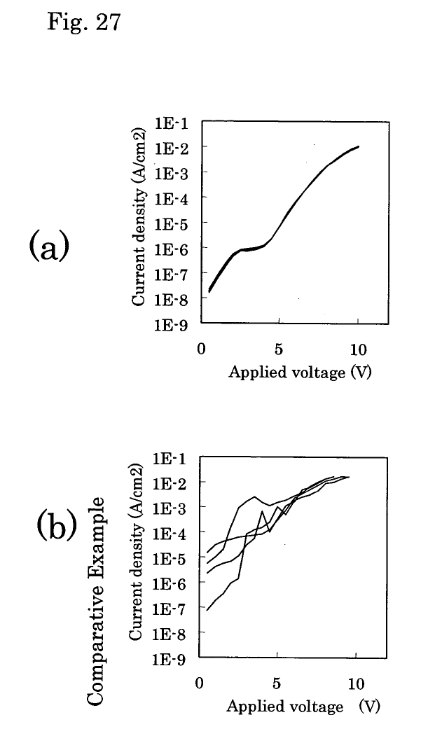

In terms of current leak, it is clearly indicated by comparing IV properties in FIGS. 27(a) and (b) that forming an initial amorphous layer improved current leak.

### Device Production Example 1-1

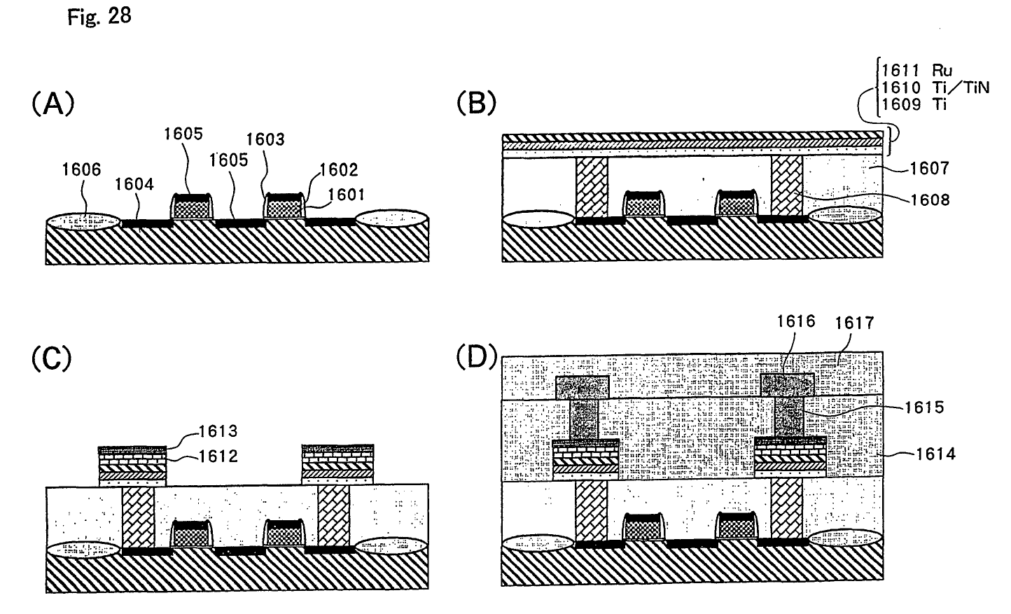

With reference to FIG. 28, there will be described Device Production Example 1-1, in which a memory cell was produced using a vapor growth process according to this invention. On a silicon substrate was deposited an oxide film by wet oxidation. After ion-implanting of dopants such as boron and phosphorous, n-type and p-type wells were formed. Then, a gate and a diffusion layer were formed as follows. First, a gate oxide film 1601 was formed by wet oxidation, and a polysilicon film 1602 to be a gate was deposited and etched. On the polysilicon film was deposited a silicon oxide film, which was then etched to form a side-wall oxide film 1603. Then, dopants such as boron and arsenic were ion-implanted to form an n-type and a p-type diffusion layers 1604. On the surface was deposited a Ti film, which was then reacted with silicon. Unreacted Ti was etched off to form Ti silicide layers 1605 on a gate 1602 and a diffusion layer 1604. By the above process, an n-type and a p-type MOS transistors which were separated by a separating oxide film 1606 from each other were formed on the silicon substrate as shown in FIG. 28(A).

Then, a contact and a lower electrode were formed as shown in FIG. 28(B). First, on a substrate was deposited a silicon oxide film or a silicon oxide film containing dopants such as boron (BPSG) as the first interlayer insulating film 1607, which was then leveled by CMP. Then, a contact was opened by etching, dopants were implanted into each of the n-type and the p-type diffusion layers, and the product was heated at 750° C. for 10 sec. Then, Ti and TiN as a barrier metal were deposited. On the metal layers was deposited tungsten by CVD, and a tungsten plug 1608 was formed by CMP. The tungsten plug may be formed by etching back of tungsten after CVD. On the surface were sequentially formed a Ti film 1609, a TiN film 1610 and Ti as capacitor lower electrode layers, on which a Ru film 1611 was then deposited to 100 nm.

Then, a ferroelectric capacitor was formed as shown in FIG. 28(C). A PZT was formed to 100 nm using a process according to this invention. Sources materials were lead bis(dipivaloylmethanate) (Pb(DPM)₂), titanium isopropoxide (Ti (OiPr)₄), zirconium butoxide (Zr(OtBu)₄) and an oxidizing agent was NO₂. Deposition conditions were as follows. First, for forming initial crystal nuclei of PTO, deposition was conducted at a substrate temperature of 380° C., under the conditions of Pb(DPM)₂ at 0.2 sccm, Ti(OiPr)₄ at 0.25 sccm and NO₂ at 3.0 sccm for 30 sec. Then, after raising a substrate temperature to 430° C., deposition was conducted under modified source gas feeding conditions: Pb(DPM)₂ at 0.25 sccm, Zr(OtBu)₄ at 0.225 sccm, Ti(OiPr)₄ at 0.2 sccm, NO₂ at 3.0 sccm and N₂ at 150 sccm for 1200 sec to form a metal-oxide dielectric film of PZT 1612.

The total gas pressure in the vacuum vessel during growth was 8×10⁻² Torr, and a grown film thickness of 250 nm. Ru 1613 was deposited by sputtering, and a capacitor upper electrode layer was formed. The capacitor upper electrode layer, a metal oxide dielectric film and a capacitor lower electrode layer were patterned by dry etching to provide PZT capacitors.

On the surface was formed a capacitor upper electrode as shown in FIG. 28(D). After forming a silicon oxide film as the second interlayer insulating film 1614 by plasma CVD, a capacitor upper contact and a plate-line contact were opened by etching. On the surface were sequentially deposited WSi, TiN, AlCu and TiN, which was then processed by etching to form a plug 1615 and the second metal interconnection 1616. On the surface were formed a silicon oxide film and an SiON film as a passivation film 1617. Then an interconnection pad (not shown) was opened for evaluation of electric properties.

### Device Production Example 1-2

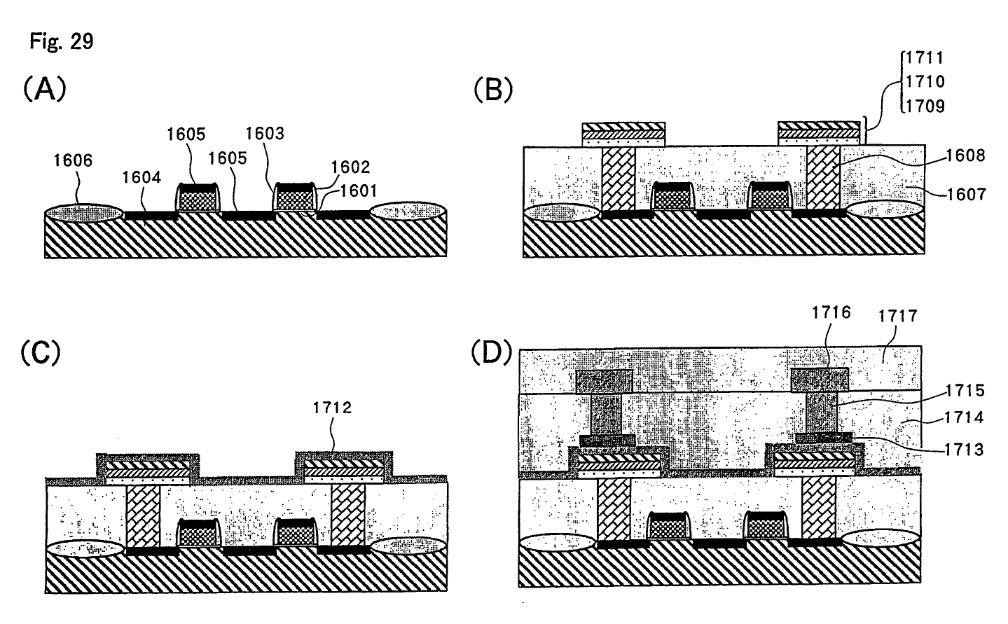

While FIG. 28 showed a process for separating capacitors by dry etching after forming the capacitor lower electrode, the capacitors may also be made, as shown in Device Production Example 1-2 as a modified process, by the process in which after separating the capacitor lower electrode, i.e., Ru/Ti/TiN/Ti by dry etching, PZT is deposited, a Ru upper electrode is formed and then the upper electrodes are separated. There will be briefly described Device Production Example 1-2 with reference to FIG. 29. In FIGS. 29 to 32, common members with FIG. 28 are indicated by the same symbols.

First, on a silicon substrate was formed a transistor as described in Production Example 1-1 (FIG. 29(A)), and were further formed the first interlayer insulating film 1607 and a plug 1608 buried therein. Then, a Ti film 1709, a TiN film 1710 and Ti were sequentially deposited by sputtering as a capacitor lower electrode layer, and then on the surface was deposited a Ru film 1711 to 100 nm. Then, a laminated structure of Ru/Ti/TiN/Ti was processed by dry etching for cell separation to form capacitor lower electrodes (FIG. 29(B)).

Subsequently, over the whole surface of the substrate was deposited a PZT film 1712 (FIG. 29(C)). After forming a Ru film, the Ru film was processed by dry etching and separated to form a capacitor upper electrode 1713. Then, the second interlayer insulating film 1714, a plug 1715, the second aluminum interconnection 1716 and a cover film 1717 were formed as described for the example shown in FIG. 16 to provide a final semiconductor device (FIG. 29(D)).

Using this method, a film subject to dry etching is so thin that a finer pattern can be formed. Since the sides of the PZT are not exposed to plasma during dry etching, no defects may generate in the PZT film.

### Device Production Example 1-3

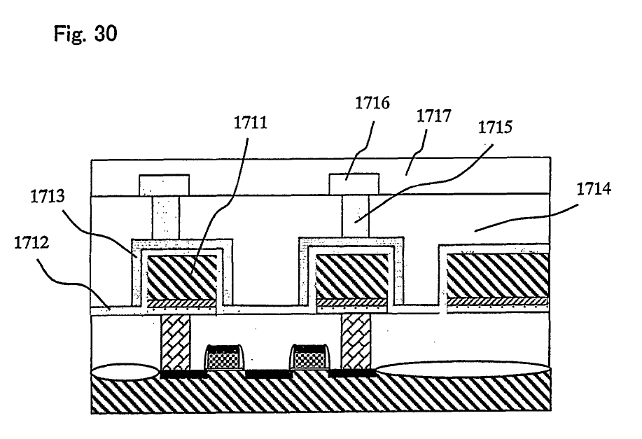

As shown in FIG. 30, Device Production Example 1-3 shows an example in which the side of a lower electrode is also used a capacitor electrode.

For forming such a structure, a capacitor lower electrode is formed to a thickness of, for example, about 500 nm in Production Example 1-2. Generally, after deposition a thick Ru film 1711, the Ru film are separated to cells by dry etching, and then a PZT film 1712 is deposited over the whole surface of the substrate. Since this invention employs thermal CVD, the PZT film can be formed with good step coverage. After depositing a Ru film, the Ru film is separated such that it covers the PZT film formed on the side of the lower electrode as shown in FIG. 30 to form a capacitor upper electrode 1713. A subsequent procedure is conducted as described in Production Example 1-2 to provide a semiconductor device.

There will be described electric properties for the capacitors produced in Device Production Examples 1-1, 1-2 and 1-3.

Five thousand 1×1 μm PZT capacitors were connected in parallel and were determined for their properties. A difference between inversion charge and non-inversion charge was 30 μC/cm² or more, indicating good dielectric properties. A leak current was as good as 10⁻⁴ A/cm² or less at an applied voltage of 10 V. Fatigue properties and retention properties were also good. A transistor with a gate length of 0.26 μm were evaluated for its properties. For both p-type and n-type transistors, variation of a threshold Vt was as good as within 10 W over the entire surface of the wafer. A resistance of a 0.4 μm square capacitor lower contact was determined using a contact chain to give a good result that a resistance per a contact was 10 Ωcm or less. Furthermore, the PZT film deposited had improved flatness so that irregular reflection was not generated and mask alignment could be precisely conducted.

Variation in a bit-line voltage difference of the capacitive element was small and no defective bits were observed.

### Device Production Example 2

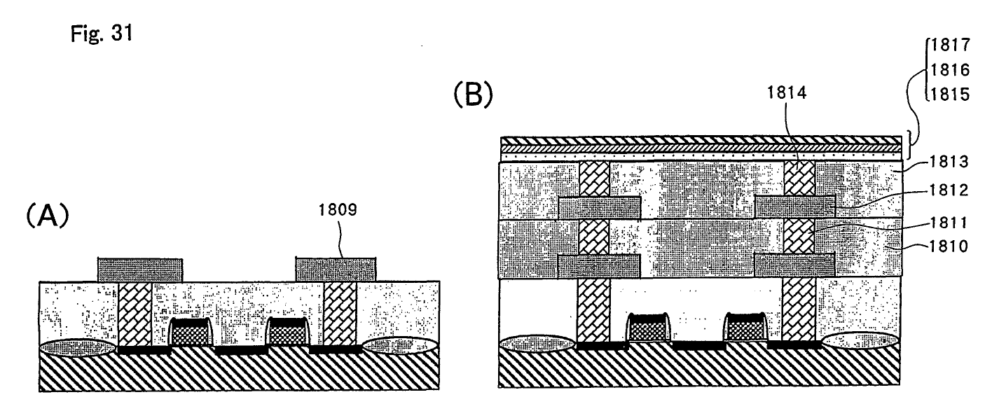

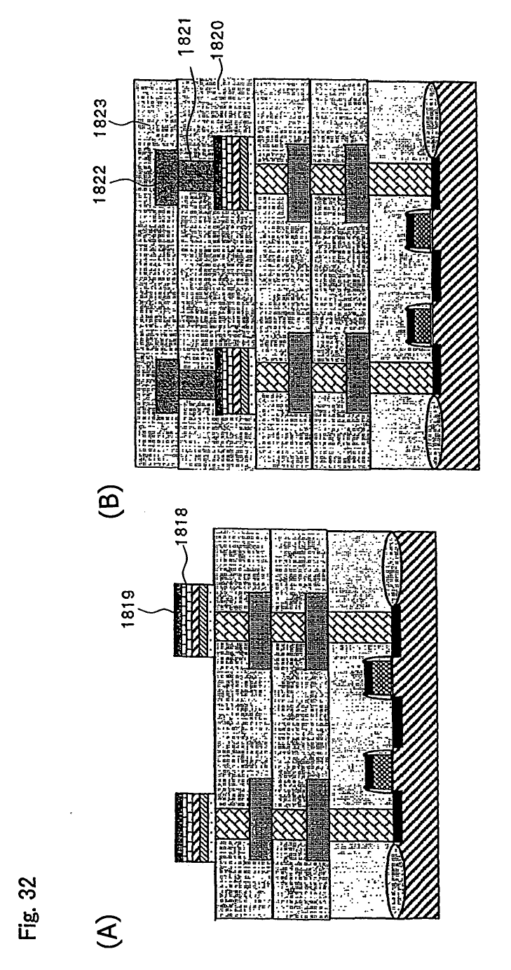

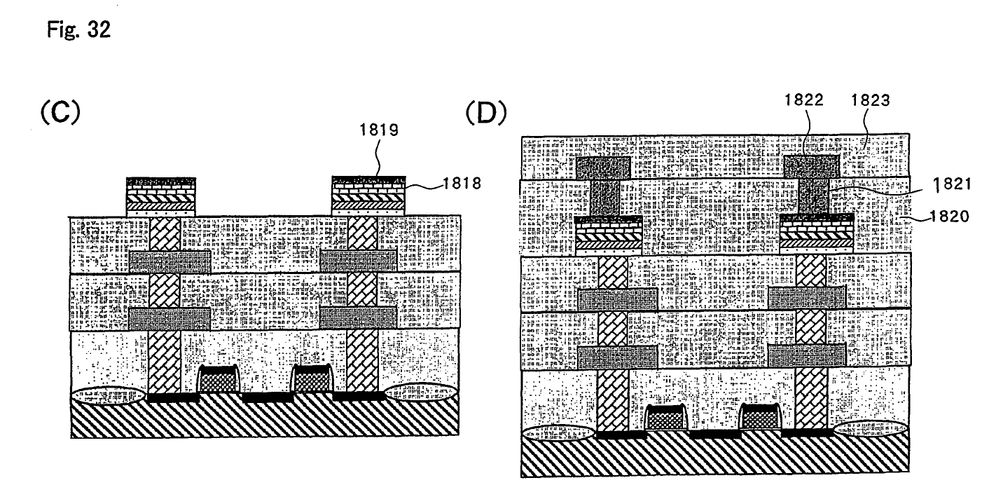

The second process for producing memory cells in accordance with an embodiment of this invention will be described with reference to FIGS. 31 and 32. The process till formation of a tungsten plug was conducted as described in the first embodiment for a memory cell. Then, on the surface were deposited Ti and TiN. An AlCu film was deposited by sputtering and the first aluminum interconnection 1809 was formed by dry etching. Thus, the first aluminum interconnection was formed on an n-type and a p-type MOS transistors as shown in FIG. 31(A).

Then, a via and the second aluminum interconnection were formed as shown in FIG. 31(B). First, on a substrate was deposited a silicon oxide film or a silicon oxide film containing dopants such as boron (BPSG) as the second interlayer insulating film 1810, which was then leveled by CMP. Then, after opening a via hole by etching, Ti and TiN were deposited as a barrier metal. On the metal layers was deposited tungsten by CVD, and a tungsten plug 1811 was formed by CMP. The tungsten plug may be formed by etching back of tungsten after CVD. Ti and TiN films were formed on the surface by sputtering, the second aluminum interconnection 1812 was formed by dry etching, and then a silicon oxide film or a silicon oxide film containing dopants such as boron (BPSG) was deposited as the third interlayer insulating film 1813, which was then leveled by CMP. After opening a via hole by etching, Ti and TiN were deposited as a barrier metal. On the metal layers was deposited tungsten by CVD, and a tungsten plug 1814 was formed by CMP. The tungsten plug may be formed by etching back of tungsten after CVD. The process of forming an aluminum interconnection, an interlayer film and a via hole can be repeated to a desired number of interconnection layers. On the last tungsten plug were sequentially deposited by sputtering a Ti film 1815, a TiN film and Ti 1816 as a capacitor lower electrode, on which was then deposited a Ru film 1817 to 100 nm.

Then, a ferroelectric capacitor was formed as shown in FIG. 32(C). A PZT was formed to 100 nm using a process according to this invention. Sources materials were lead bis(dipivaloylmethanate) (Pb(DPM)₂), titanium isopropoxide (Ti(OiPr)₄), zirconium butoxide (Zr(OtBu)₄) and an oxidizing agent was NO₂. Deposition conditions were as follows. First, for forming initial crystal nuclei of PTO, deposition was conducted at a substrate temperature of 380° C., under the conditions of Pb(DPM)₂ at 0.2 sccm, Ti(OiPr)₄ at 0.25 sccm and NO₂ at 3.0 sccm for 30 sec. Then, after raising a substrate temperature to 430° C., deposition was conducted under modified source gas feeding conditions: Pb(DPM)₂ at 0.25 sccm, Zr(OtBu)₄ at 0.225 sccm, Ti(OiPr)₄ at 0.2 sccm, NO₂ at 3.0 sccm and N₂ at 150 sccm for 1200 sec to form a metal-oxide dielectric film of PZT 1818.

The total gas pressure in the vacuum vessel during growth was 8×10⁻² Torr, and a grown film thickness of 250 nm. Ru 1819 was deposited by sputtering, and a capacitor upper electrode layer was formed. The capacitor upper electrode layer, a metal oxide dielectric film and a capacitor lower electrode layer were patterned by dry etching to provide a PZT capacitor.

Then, as shown in FIG. 32(D), a silicon oxide film as the fourth interlayer insulating film 1820 was formed by plasma CVD and then a capacitor upper contact and a plate-line contact were opened by etching. Then, on the surface were sequentially deposited WSi, TiN, AlCu and TiN, which was then processed by etching to form a plug 1821 and the third metal interconnection 1822. On the surface were formed a silicon oxide film and an SiON film as a passivation film 1823. Then an interconnection pad was opened for evaluation of electric properties.

Again, also when there is a lower aluminum interconnection, PZT may be deposited after separating the capacitor lower electrode, i.e., Ru/Ti/TiN/Ti by dry etching. Then a Ru capacitor upper electrode is formed and then the capacitor upper electrodes are separated. Using this method, a film subject to dry etching is so thin that a finer pattern can be formed. Since the sides of the PZT are not exposed to plasma during dry etching, no defects may generate in the PZT film.

The memory cell produced in Device Production Example 2 was evaluated for its electric properties as described for the memory cell produced in Device Production Example 1.

As a result, a difference between inversion charge and non-inversion charge was 40 μC/cm² or more, indicating good dielectric properties. A leak current was as good as 10⁻⁴ A/cm² or less at an applied voltage of 10 V. Fatigue properties and retention properties were also good. A transistor with a gate length of 0.26 μm were evaluated for its properties. For both p-type and n-type transistors, variation of a threshold Vt was as good as within 10% over the entire surface of the wafer. A resistance of a 0.4 μm square capacitor lower contact was determined using a contact chain to give a good result that a resistance per a contact was 10 Ωcm or less. Furthermore, the PZT film deposited had improved flatness so that irregular reflection was not generated and mask alignment could be precisely conducted.

There have been described Device Production Examples in which tungsten was used as a contact, but devices using a polysilicon contact also exhibited improvement in ferroelectric capacitor properties, transistor properties and a contact resistance.

Although low-temperature nucleation has been used in Device Production Examples, high-pressure nucleation or a combination of low-temperature nucleation and high-pressure nucleation may be employed to give equivalently good results. Furthermore, a semiconductor device may be manufactured employing a process forming an initial amorphous layer, whereby leak current property may be improved and mask alignment may be conducted with a higher precision.

### Industrial Applicability

Vapor growth process of a metal-oxide dielectric film such as a PZT film (Pb(Zr, Ti)O₃ film) by low-temperature nucleation and/or high-pressure nucleation according to this invention can be used to produce a dielectric film with a reduced leak current and good film transparency, whereby mask alignment can be easily conducted. The process can be applied to a capacitive element to produce a highly-integrated semiconductor device with small variation in a bit-line voltage difference in a good yield.

Vapor growth process of a metal-oxide dielectric film by a process forming an initial amorphous layer according to this invention can be used to produce a dielectric film with a reduced leak current and good film transparency, whereby mask alignment can be easily conducted.

A PZT film produced according to this invention has a small grain size (50 nm to 200 nm) which cannot be achieved by a conventional method, even when it is formed on the surface of a base conductor material such as Ru. It can, therefore, exhibit good properties in terms of a leak current, mask alignment and variation in a bit-line voltage difference.

What is claimed is:

1. A vapor growth process for forming a metal-oxide dielectric film having a perovskite type of crystal structure represented by ABO₃ on a base conductor material using organometallic source gases, comprising:
a first step of forming initial perovskite crystal nuclei or an initial amorphous layer having an amorphous structure on the base conductor material under a first deposition conditions; and
a second step of further growing a film having a perovskite crystal structure on the initial crystal nuclei or the initial amorphous layer formed in the first step under a second deposition conditions which are different from the first deposition conditions;
wherein the first conditions meet at least one of the following requirements:
(a) a lower substrate temperature than that in the second deposition conditions; and
(b) a higher source gas pressure than that in the second deposition conditions.

2. The vapor growth process for forming a metal-oxide dielectric film as claimed in claim 1 wherein in the first and the second conditions, a pressure is the same and a substrate temperature is lower in the first deposition conditions.

3. The vapor growth process for forming a metal-oxide dielectric film as claimed in claim 1 wherein in the first and the second conditions, a substrate temperature is the same and a pressure is higher in the first deposition conditions.

4. The vapor growth process for forming a metal-oxide dielectric film as claimed in claim 1 wherein in the first and the second conditions, the first deposition conditions meet both requirements (a) a lower substrate temperature than that in the second deposition conditions and (b) a higher pressure than that in the second deposition conditions.

5. The vapor growth process for forming a metal-oxide dielectric film as claimed in any of claims 1 to 4 wherein all of the organometallic source gases to be materials for a metal-oxide dielectric are used under the first deposition conditions to form initial nuclei or an initial amorphous layer and a film having a perovskite crystal structure is grown using all of the organometallic source gases under the second deposition conditions while changing the feeding conditions.

6. The vapor growth process for forming a metal-oxide dielectric film as claimed in any of claims 1 to 4 wherein a portion of the organometallic source gases to be materials for a metal-oxide dielectric are used under the first deposition conditions to form initial nuclei or an initial amorphous layer and a film having a perovskite crystal structure is grown using all of the organometallic source gases under the second deposition conditions.

7. The vapor growth process for forming a metal-oxide dielectric film as claimed in claim 6 wherein when at least one of elements A and B contains a plurality of elements, the organometallic source gases used in the first deposition conditions contains both element A source and element B source.

8. The vapor growth process for forming a metal-oxide dielectric film as claimed in any of claims 1 to 7 wherein deposition under the second deposition conditions is conducted feeding source gases with good self-controllability, and deposition under the first deposition conditions is conducted feeding an element A source in a larger amount than that in the second deposition conditions.

9. The vapor growth process for forming a metal-oxide dielectric film as claimed in any of claims 1 to 8 wherein when using both Zr and Ti as an element B, deposition is conducted with a smaller ratio of a Zr source /a Ti source in the first deposition conditions than in the second deposition conditions.

10. The vapor growth process for forming a metal-oxide dielectric film as claimed in claim 6 wherein when using Zr and other element(s) as an element B, deposition under the first deposition conditions is conducted without feeding a Zr source gas.

11. The vapor growth process for forming a metal-oxide dielectric film as claimed in any of claims 1 to 7 wherein deposition is conducted while controlling a grain size by controlling at least one of a temperature and a source gas pressure in the first deposition conditions.

12. The vapor growth process for forming a metal-oxide dielectric film as claimed in any of claims 1 to 11 wherein deposition is conducted while the total pressure of the source gases in the second deposition conditions is maintained at 200 mTorr or less.

13. The vapor growth process for forming a metal-oxide dielectric film as claimed in any of claims 1 to 12 wherein a substrate temperature in the second deposition conditions is 470° C. or lower.

14. The vapor growth process for forming a metal-oxide dielectric film as claimed in any of claims 1 to 7 wherein the metal-oxide dielectric film is a PZT or BST film.

15. The vapor growth process for forming a metal-oxide dielectric film as claimed in any of claims 1 to 14 wherein the base conductor material is a capacitor electrode comprising at least on its surface a film made of a metal or metal oxide selected from Ir, Ru., IrO₂ and RuO₂.

16. The vapor growth process for forming a metal-oxide dielectric film as claimed in any of claims 1 to 14 wherein the base conductor material is of a four-layer structure of Ru/Ti/TiN/Ti.

17. The vapor growth process for forming a metal-oxide dielectric film as claimed in any of claims 1 to 14 wherein the base conductor material is of a five-layer structure of Ru/Ti/TiN/Ti/W.

18. A process for manufacturing a semiconductor device comprising steps of forming an MOS transistor on a semiconductor substrate; forming a first interlayer insulating film on the transistor; opening, in the first interlayer insulating film, a contact reaching a diffusion layer in the MOS transistor and filling the contact with a metal plug for electric conduction; forming a capacitor lower electrode layer over the whole surface of the first interlayer insulating film having the metal plug; depositing a metal-oxide dielectric film using the process as claimed in any of claims 1 to 17 over the capacitor lower electrode layer; forming a capacitor upper electrode layer over the metal-oxide dielectric film; patterning the lower electrode layer, the metal-oxide dielectric film and the capacitor upper electrode layer to provide a three-layer structure capacitor.

19. A process for manufacturing a semiconductor device comprising steps of forming an MOS transistor on a semiconductor substrate; forming a first interlayer insulating film on the transistor; opening, in the first interlayer insulating film, a contact reaching a diffusion layer in the MOS transistor and filling the contact with a metal plug for electric conduction; forming a capacitor lower electrode layer over the whole surface of the first interlayer insulating film having the metal plug; patterning the capacitor lower electrode layer to form a capacitor lower electrode in the metal plug; depositing a metal-oxide dielectric film using the process as claimed in any of claims 1 to 17 over the whole surface of the patterned capacitor lower electrode and the first interlayer insulating film; forming a capacitor upper electrode layer over the whole surface of the metal-oxide dielectric film; and patterning the capacitor upper electrode layer to provide a three-layer structure capacitor comprising the capacitor lower electrode, the metal-oxide dielectric film and the capacitor upper electrode.

20. A process for manufacturing a semiconductor device comprising steps of forming an MOS transistor on a semiconductor substrate; forming a first interlayer insulating film on the transistor; opening, in the first interlayer insulating film, a contact reaching a diffusion layer in the MOS transistor and filling the contact with a metal plug for electric conduction; forming an aluminum interconnection electrically connected to the metal plug on the first interlayer insulating film; forming a second interlayer insulating film on the aluminum interconnection; opening, in the second interlayer insulating film, a contact reaching the aluminum interconnection and filling the contact with a metal plug for electric conduction; forming a capacitor lower electrode layer over the whole surface of the second interlayer insulating film including the metal plug; depositing a metal-oxide dielectric film over the whole surface of the capacitor lower electrode layer by the process as claimed in any of claims 1 to 17; forming a capacitor upper electrode layer over the whole surface of the metal-oxide dielectric film; and patterning the capacitor lower electrode layer, the metal-oxide dielectric film and the capacitor upper electrode layer to provide a three-layer structure capacitor.

21. The process for manufacturing a semiconductor device as claimed in claim 20 wherein a multi-layer aluminum interconnection is formed in the lower layer of the capacitor by repeating at least once the steps of forming an aluminum interconnection electrically connected to the last metal plug formed before forming the capacitor lower electrode layer, forming an interlayer insulating film on the aluminum interconnection, and opening a contact reaching the aluminum interconnection in the interlayer insulating film and filling the opening with a metal plug for electric conduction.

22. A PZT film deposited on a base conductor material surface selected from the group consisting of Ir, Ru, IrO₂ and RuO₂ having a grain size within a range of 50 nm to 150 nm.

23. The PZT film as claimed in claim 22 wherein the PZT film is deposited by MOCVD.

24. The PZT film as claimed in claim 23 wherein the PZT film is deposited by MOCVD at 400 to 700° C.

25. A capacitive element comprising the PZT film as claimed in any of claims 22 to 24.
